(19) United States
(12) Patent Application Publication
(10) Pub. No.: US 2011/0062432 A1
(43) Pub. Date: Mar. 17, 2011

(54) SEMICONDUCTOR DEVICE AND MANUFACTURING METHOD THEREOF

(75) Inventors: Shunpei Yamazaki, Tokyo (JP); Masayuki Sakakura, Tochigi (JP); Jun Koyama, Sagamihara (JP); Yoshiaki Oikawa, Sagamihara (JP); Hotaka Maruyama, Tochigi (JP); Masami Jintyou, Shimotsuga (JP); Kenichi Okazaki, Tochigi (JP)

(73) Assignee: SEMICONDUCTOR ENERGY LABORATORY CO., LTD., Atsugi-shi (JP)

(21) Appl. No.: 12/879,635

(22) Filed: Sep. 10, 2010

(30) Foreign Application Priority Data
Sep. 16, 2009 (JP) 2009-215050

(51) Int. Cl. H01L 29/786; H01L 21/44

(52) U.S. Cl. 257/43; 438/104; 257/E29.296; 257/E21.476

(57) ABSTRACT

An object is to realize low power consumption while manufacturing a semiconductor device including a thin film transistor whose parasitic capacitance is reduced. Part of an insulating layer covering the periphery of a gate electrode layer is formed to be thick. Specifically, a stack including a spacer insulating layer and a gate insulating layer is formed. The thick part of the insulating layer covering the periphery of the gate electrode layer reduces parasitic capacitance formed between the gate electrode layer of the thin film transistor and another electrode layer (another wiring layer) overlapping with the gate electrode layer.

### TECHNICAL FIELD

The present invention relates to a semiconductor device including an oxide semiconductor and a manufacturing method thereof.

In this specification, a semiconductor device generally means a device which can function by utilizing semiconductor characteristics, and an electro-optic device, a semiconductor circuit, and an electronic appliance are all semiconductor devices.

### BACKGROUND ART

In recent years, a technique for forming a thin film transistor (TFT) by using a thin semiconductor film (having a thickness of approximately several nanometers to several hundred nanometers) formed over a substrate having an insulating surface has attracted attention. Thin film transistors are applied to a wide range of electronic devices such as ICs or electro-optical devices, and prompt development of thin film transistors that are to be used as switching elements in image display devices, in particular, is being pushed.

Various metal oxides are used for a variety of applications. Some metal oxides have semiconductor characteristics. Examples of such metal oxides having semiconductor characteristics include tungsten oxide, tin oxide, indium oxide, zinc oxide, and the like. Thin film transistors in which a channel formation region is formed of such metal oxides having semiconductor characteristics are known (Patent Documents 1 and 2).

As electronic devices in which a thin film transistor is used, there are mobile devices such as a mobile phone or a personal computer, and the like. For such a portable electronic device, power consumption which affects continuous operating time is a big problem. Also for a television set which is increasing in size, it is important to suppress the increase in power consumption associated with the increase in size.

### REFERENCE

### [Patent Documents]

[Patent Document 1] Japanese Published Patent Application No. 2007-123861
[Patent Document 2] Japanese Published Patent Application No. 2007-096055

### DISCLOSURE OF INVENTION

An object is to provide a semiconductor device including a thin film transistor having an oxide semiconductor layer, which realizes low power consumption.

Further, an object is to provide a semiconductor device including a thin film transistor having an oxide semiconductor layer, which has high reliability.

In order to reduce power consumption of a semiconductor device, part of an insulating layer covering the periphery of a gate electrode layer is formed to be thick. Specifically, a stack including a spacer insulating layer and a gate insulating layer is formed. The thick part of the insulating layer covering the periphery of the gate electrode layer reduces parasitic capacitance formed between the gate electrode layer of the thin film transistor and another electrode layer (another wiring layer) overlapping with the gate electrode layer. Meanwhile, in a region where capacitance is to be formed, only a gate insulating layer is used as a dielectric and thus the thickness of the dielectric is reduced, so that the capacitance is increased.

After a thick spacer insulating layer with a thickness of 1 μm to 2 μm inclusive, which covers the gate electrode layer, is formed, the spacer insulating layer is selectively removed. A gate insulating layer with a thickness smaller than the spacer insulating layer is formed thereover, so that a stacked-layer region having a large thickness and a single-layer region having a small thickness are partly formed. The region having a large thickness is formed using a stack including the spacer insulating layer and the gate insulating layer, in order to reduce the parasitic capacitance. On the other hand, the region having a small thickness is formed using only the gate insulating layer, in order to form a storage capacitor or the like.

An embodiment of the present invention which is disclosed in the present specification is a semiconductor device including a gate electrode layer over a substrate; an insulating layer which is in contact with a side surface of the gate electrode layer and has a tapered side surface over the gate electrode layer; over the insulating layer, a gate insulating layer which is thinner than the insulating layer and is in contact with a top surface of the gate electrode layer; an oxide semiconductor layer over the gate insulating layer; a source electrode layer and a drain electrode layer over a stack including the insulating layer, the gate insulating layer, and the oxide semiconductor layer; and an oxide insulating layer in contact with the oxide semiconductor layer, over the source electrode layer and the drain electrode layer.

Note that in the structure, the insulating layer is covered with the gate insulating layer; therefore, the source electrode and the drain electrode layer are not in contact with the insulating layer having a tapered side surface.

With the structure, at least one of the objects can be achieved. With the use of the structure, the parasitic capacitance formed between the gate electrode layer and the drain electrode layer can be reduced. Thus, low power consumption can be achieved.

In the structure, part of the insulating layer in the periphery of the gate electrode layer is formed to be thick, so that the withstand voltage between the gate electrode layer and the oxide semiconductor layer can be improved.

An embodiment of the present invention for realizing the structure is a method for manufacturing a semiconductor device, including the steps of forming a gate electrode layer over a substrate; forming an insulating film covering the gate electrode layer; forming an insulating layer covering a side surface of the gate electrode layer, by forming an opening reaching a top surface of the gate electrode layer through selective etching of the insulating film; over the insulating layer, forming a gate insulating layer which is thinner than the insulating layer and is in contact with the top surface of the gate electrode layer; forming an oxide semiconductor layer over the gate insulating layer, forming a source electrode layer and a drain electrode layer over a stack including the insulating layer, the gate insulating layer, and the oxide semiconductor layer; and forming an oxide insulating layer in contact with the oxide semiconductor layer, over the source electrode layer and the drain electrode layer.

In the method, the insulating film is formed using a film formation apparatus which is different from a film formation apparatus used for forming the gate insulating layer, and the gate insulating layer is formed using a high-density plasma apparatus. Therefore, the gate insulating layer is denser than the insulating layer provided in contact with a bottom surface of the gate insulating layer. The etching rate of the gate insulating layer can be lower than the etching rate of the insulating layer by 10% or more or 20% or more in the case where the etching rates with the same etchant are compared to each other.

In the method, heating at a temperature of 400° C. to 750° C. inclusive is preferably performed using a RTA apparatus after the oxide semiconductor layer is formed over the gate insulating layer. When high-temperature heating is performed with the use of RTA (GRTA or LRTA), in the vicinity of a surface of the oxide semiconductor film, needle-like crystals might be generated in a direction perpendicular to the surface (c-axis orientation). With the heat treatment using a RTA apparatus, the thin film transistor can be improved in electric characteristics (field-effect mobility and the like) or reliability.

Further, a resist mask formed using a multi-tone mask can be used. In the case of using a multi-tone mask, an oxide semiconductor layer in contact with bottom surfaces of the source electrode layer and the drain electrode layer is included. Another embodiment of the present invention is a semiconductor device including a gate electrode layer over a substrate; an insulating layer which is in contact with a side surface of the gate electrode layer and has a tapered side surface over the gate electrode layer; over the insulating layer, a gate insulating layer which is thinner than the insulating layer and is in contact with a top surface of the gate electrode layer; an oxide semiconductor layer over the gate insulating layer; a source electrode layer and a drain electrode layer over the oxide semiconductor layer; and an oxide insulating layer in contact with a side surface of the oxide semiconductor layer, over the source electrode layer and the drain electrode layer.

With the structure, at least one of the objects can be resolved.

In the structure, the source electrode layer and the drain electrode layer are not in contact with the gate insulating layer. It is needless to say that, in the structure, the source electrode layer and the drain electrode layer are not in contact with the insulating layer having a tapered side surface since the insulating layer is covered with the gate insulating layer.

In each of the structures, the gate insulating layer has a stacked-layer structure including a silicon nitride film or a silicon oxide film. Further, in each of the structures, an aluminum oxide film or a silicon oxide film formed by a sputtering method is used as the oxide insulating layer.

In each of the structures, the parasitic capacitance in a portion where a wiring overlaps with another wiring can be reduced. Thus, a short circuit between the wirings can be prevented.

In each of the structures, in a portion where capacitance is to be formed, an opening is provided in the insulating layer, and only a thin gate insulating layer is used as a dielectric. Thus, large capacitance can be formed.

For a semiconductor device including a thin film transistor having an oxide semiconductor layer, low power consumption can be realized.

### BRIEF DESCRIPTION OF DRAWINGS

FIGS. 1A to 1D are cross-sectional views illustrating an embodiment of the present invention.

FIG. 2 is a cross-sectional view illustrating an embodiment of the present invention.

FIGS. 3A to 3D are cross-sectional views illustrating an embodiment of the present invention.

FIG. 4 is a cross-sectional view illustrating an embodiment of the present invention.

FIGS. 5A to 5C are top views and a cross-sectional view which illustrate an embodiment of the present invention.

FIG. 6 is a cross-sectional view illustrating an embodiment of the present invention.

FIG. 7 is a top view illustrating an embodiment of the present invention.

FIG. 8 is a top view illustrating an embodiment of the present invention.

FIG. 9 is an equivalent circuit diagram illustrating an embodiment of the present invention.

FIG. 10 is a cross-sectional view illustrating an embodiment of the present invention.

FIG. 11 is an equivalent circuit diagram illustrating an embodiment of the present invention.

FIGS. 12A to 12C are cross-sectional views illustrating an embodiment of the present invention.

FIGS. 13A and 13B are a top view and a cross-sectional view which illustrate an embodiment of the present invention.

FIGS. 14A and 14B are block diagrams of a display device.

FIGS. 15A and 15B are a circuit diagram of a signal line driver circuit and a timing chart of the signal line driver circuit.

FIGS. 16A to 16D are circuit diagrams illustrating a shift register.

FIGS. 17A and 17B are a circuit diagram of a shift register and a timing chart illustrating an operation of the shift register.

FIGS. 18A and 18B are a top view and a cross-sectional view which illustrate an embodiment of the present invention.

FIGS. 19A to 19C are an equivalent circuit diagram, a top view, and a cross-sectional view which illustrate an embodiment of the present invention.

FIGS. 20A and 20B are diagrams each illustrating an example of an electronic appliance.

FIGS. 21A and 21B are diagrams each illustrating an example of an electronic appliance.

FIG. 22 is a diagram illustrating an example of an electronic appliance.

FIG. 23 is a diagram illustrating an example of an electronic appliance.

FIG. 24 is a diagram illustrating an example of an electronic appliance.

### BEST MODE FOR CARRYING OUT THE INVENTION

Embodiments of the present invention will be described below in detail with reference to drawings. However, the present invention is not limited to the description below, and it is easily understood by those skilled in the art that modes and details disclosed herein can be modified in various ways without departing from the spirit and the scope of the present invention. Therefore, the present invention is not construed as being limited to description of the embodiments.

### Embodiment 1

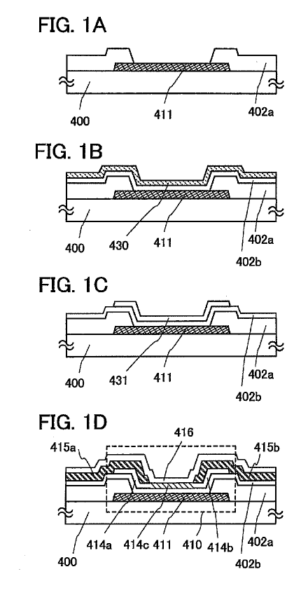

In this embodiment, one of bottom-gate thin film transistors which is manufactured over a substrate and called a channel-etched type is described. FIG. 1D illustrates a cross-sectional structure of the thin film transistor.

A thin film transistor 410 illustrated in FIG. 1D is a channel-etched thin film transistor and includes, over a substrate 400 having an insulating surface, a gate electrode layer 411; an insulating layer 402a; a gate insulating layer 402b; an oxide semiconductor layer including at least a channel formation region 414c, a high-resistance source region 414a, and a high-resistance drain region 414b; a source electrode layer 415a; and a drain electrode layer 415b. In addition, an oxide insulating layer 416 which covers the thin film transistor 410 and is in contact with the channel formation region 414c, is provided.

The insulating layer 402a is at least five times as thick as the gate insulating layer 402b. The insulating layer 402a has an opening which exposes a top surface of the gate electrode layer 411, and a side surface of the opening is tapered. A bottom surface of the gate insulating layer 402b is in contact with the top surface of the gate electrode layer 411. The oxide semiconductor layer is in contact with a top surface of the gate insulating layer 402b.

A process of manufacturing the thin film transistor 410 over a substrate is described below with reference to FIGS. 1A to 1D.

First, a conductive film is formed over the substrate 400 having an insulating surface, and then, the gate electrode layer 411 is formed by a first photolithography step. Note that a resist mask may be formed by an inkjet method. A photomask is not used when the resist mask is formed by an inkjet method, which results in reducing manufacturing costs.

There is no particular limitation on a substrate that can be used as the substrate 400 having an insulating surface as long as it has at least heat resistance to withstand heat treatment performed later. As the substrate 400 having an insulating surface, a glass substrate of barium borosilicate glass, aluminoborosilicate glass, or the like can be used.

When the temperature of the heat treatment performed later is high, a substrate having a strain point of 730° C. or higher is preferably used as the glass substrate. As a material for the glass substrate, a glass material such as aluminosilicate glass, aluminoborosilicate glass, or barium borosilicate glass is used, for example. Note that by containing a larger amount of barium oxide (BaO) than boric acid, more-practical heat resistant glass can be obtained. Therefore, a glass substrate containing a larger amount of BaO than B₂O₃ is preferably used.

Note that, instead of the glass substrate described above, a substrate formed using an insulator such as a ceramic substrate, a quartz substrate, or a sapphire substrate may be used as the glass substrate. Alternatively, crystallized glass or the like may be used.

The gate electrode layer 411 can be formed using an element selected from Al, Cr, Cu, Ta, Ti, Mo, and W, an alloy containing any of these elements, an alloy containing a combination of any of these elements, or the like.

The insulating layer 402a to be a spacer insulating layer is formed over the gate electrode layer 411.

The insulating layer 402a can be formed to have a single-layer structure or a stacked-layer structure of a silicon oxide layer, a silicon nitride layer, a silicon oxynitride layer, and/or a silicon nitride oxide layer by a plasma CVD method, a sputtering method, or the like. For example, when a silicon oxynitride layer is formed, it may be formed by a plasma CVD method using SiH₄, oxygen, and nitrogen as a deposition gas. The film thickness of the insulating layer 402a is 500 nm to 2 μm inclusive. In this embodiment, a silicon oxynitride film (also referred to as SiOₓN_{y}, where x>y>0) with a film thickness of 1 μm is formed by a PCVD method using a parallel plate PCVD apparatus.

Subsequently, the opening overlapping with the gate electrode layer 411 is formed in the insulating layer 402a by a second photolithography step. In this embodiment, the opening is formed by dry etching. Note that in order to improve coverage by a film formed over the insulating layer 402a later, the insulating layer 402a is preferably tapered by controlling an etching condition. FIG. 1A is a cross-sectional view of this stage. Further, also in the case where an electrode layer formed in the same step as the gate electrode layer 411 is used to form a capacitance such as a storage capacitor, an opening overlapping with a region where the capacitance is to be formed is provided in the insulating layer 402a. Furthermore, a contact hole for electrically connecting a wiring layer formed in the same step as the gate electrode layer and a wiring layer to be provided in the upper portion later, is also formed using the same photomask as the opening.

Next, the gate insulating layer 402b is formed. The gate insulating layer 402b can be formed to have a single-layer structure or a stacked-layer structure of a silicon oxide layer, a silicon nitride layer, a silicon oxynitride layer, and/or a silicon nitride oxide layer by a plasma CVD method, a sputtering method, or the like. For example, a stack including a silicon nitride film and a silicon oxide film is used. The film thickness of the gate insulating layer 402b is 50 nm to 200 nm inclusive.

In this embodiment, the gate insulating layer 402b is formed using a high-density plasma apparatus. Here, a high-density plasma apparatus refers to an apparatus which can realize a plasma density higher than or equal to 1×10¹¹/cm³. For example, plasma is generated by applying a microwave power higher than or equal to 3 kW and lower than or equal to 6 kW so that an insulating film is formed.

A monosilane gas (SiH₄), nitrous oxide (N₂O), and a rare gas are introduced into a chamber as a source gas to generate high-density plasma at a pressure higher than or equal to 10 Pa and lower than or equal to 30 Pa so that an insulating film is formed over a substrate having an insulating surface, such as a glass substrate. After that, the supply of a monosilane gas is stopped, and nitrous oxide (N₂O) and a rare gas are introduced without exposure to the air, so that plasma treatment may be performed on a surface of the insulating film The plasma treatment performed on the surface of the insulating film by introducing nitrous oxide (N₂O) and a rare gas is performed at least after the insulating film is formed. The insulating film formed through the above process procedure has a small thickness and corresponds to an insulating film whose reliability can be ensured even though it has a thickness less than 100 nm, for example.

In forming the gate insulating layer 402b, the flow ratio of a monosilane gas (SiH₄) to nitrous oxide (N₂O) which are introduced into the chamber is in the range of 1:10 to 1:200. In addition, as a rare gas which is introduced into the chamber, helium, argon, krypton, xenon, or the like can be used. In particular, argon, which is inexpensive, is preferably used.

In addition, since the insulating film formed using the high-density plasma apparatus can have a uniform thickness, the insulating film has excellent step coverage. Further, as for the insulating film formed using the high-density plasma apparatus, the thickness of a thin film can be controlled precisely.

The insulating film formed through the above process procedure is greatly different from the insulating film formed using a conventional parallel plate plasma CVD apparatus. The etching rate of the insulating film formed through the above process procedure is lower than that of the insulating film formed using the conventional parallel plate plasma CVD apparatus by 10% or more or 20% or more in the case where the etching rates with the same etchant are compared to each other. Thus, it can be said that the insulating film formed using the high-density plasma apparatus is a dense film. The gate insulating layer 402b is a film denser than the insulating layer 402a.

In this embodiment, a silicon oxynitride film (also referred to as SiOₓN_{y}, where x>y>0) with a thickness of 100 nm formed using the high-density plasma apparatus is used as the gate insulating layer 402b.

Further, an insulating film serving as a base film may be provided between the substrate 400 and the gate electrode layer 411. The base film has a function of preventing diffusion of an impurity element from the substrate 400, and can be formed to have a single-layer structure or a stacked-layer structure using one or more of a silicon nitride film, a silicon oxide film, a silicon nitride oxide film, and a silicon oxynitride film.

Next, an oxide semiconductor film 430 is formed to a thickness of 2 nm to 200 nm inclusive over the gate insulating layer 402b (see FIG. 1B). Alternatively, the oxide semiconductor film 430 can be formed by a sputtering method in a rare gas (typically argon) atmosphere, an oxygen atmosphere, or an atmosphere of a rare gas (typically argon) and oxygen. In this embodiment, the oxide semiconductor film is formed to a thickness of 30 nm in an oxygen atmosphere, an argon atmosphere, or a mixed atmosphere of argon and oxygen under a condition that a target is a target for film formation of an oxide semiconductor containing In, Ga, and Zn (a target for film formation of an In—Ga—Zn—O-based oxide semiconductor (In₂O₃:Ga₂O₃:ZnO=1:1:1 (molar ratio)), the distance between the substrate and the target is 170 mm, pressure is 0.4 Pa, and a direct current (DC) power source is 0.5 kW. As the target for film formation of an oxide semiconductor containing In, Ga, and Zn, a target having a composition ratio of In₂O₃:Ga₂O₃:ZnO=1:1:2 (molar ratio) or a target having a composition ratio of In₂O₃:Ga₂O₃:ZnO=1:1:4 (molar ratio) can also be used. In the case of using a sputtering method, a target containing SiO₂ at 2 wt % to 10 wt % inclusive, may be used.

As the metal oxide used for the oxide semiconductor layer, the following metal oxides can also be used: a four-component metal oxide such as an In—Sn—Ga—Zn—O-based oxide semiconductor; a three-component metal oxide such as an In—Sn—Zn—O-based oxide semiconductor, an In—Al—Zn—O-based oxide semiconductor, a Sn—Ga—Zn—O-based oxide semiconductor, an Al—Ga—Zn—O-based oxide semiconductor, and a Sn—Al—Zn—O-based oxide semiconductor; a two-component metal oxide such as an In—Zn—O-based oxide semiconductor, a Sn—Zn—O-based oxide semiconductor, an Al—Zn—O-based oxide semiconductor, a Zn—Mg—O-based oxide semiconductor, a Sn—Mg—O-based oxide semiconductor, an In—Ga—O-based oxide semiconductor, an In—Mg—O-based oxide semiconductor; an In—O-based oxide semiconductor; and a Sn—O-based oxide semiconductor. Further, SiO₂ may be contained in the above oxide semiconductor.

Further, preheat treatment is preferably performed before the oxide semiconductor film 430 is formed, in order to remove moisture or hydrogen which remains on an inner wall of a sputtering apparatus, on a surface of the target, or inside a target material. As the preheat treatment, a method in which the inside of the film formation chamber is heated to higher than or equal to 200° C. and lower than or equal to 600° C. under reduced pressure, a method in which introduction and exhaust of nitrogen or an inert gas are repeated while the inside of the film formation chamber is heated, and the like can be given. After the preheat treatment, the substrate or the sputtering apparatus is cooled. Then, an oxide semiconductor film is formed without exposure to the air. In this case, not water but oil or the like is preferably used as a coolant for the target. Although a certain level of effect can be obtained when introduction and exhaust of nitrogen are repeated without heating, it is preferable to perform the treatment with the inside of the film formation chamber heated.

Then, the oxide semiconductor film 430 is processed into an island-like oxide semiconductor layer by a third photolithography step. A resist mask for forming the island-like semiconductor layer may be formed by an inkjet method. A photomask is not used when the resist mask is formed by an inkjet method, which results in reducing manufacturing costs.

Next, the oxide semiconductor layer is subjected to dehydration or dehydrogenation. The temperature of first heat treatment for dehydration or dehydrogenation is higher than or equal to 400° C. and lower than or equal to 750° C., preferably higher than or equal to 400° C. and lower than the strain point of the substrate. In this embodiment, heating is performed at 650° C. for six minutes with the use of a GRTA apparatus which performs heat treatment using a high-temperature nitrogen gas, and then, the oxide semiconductor layer is not exposed to the air and water and hydrogen are prevented from being mixed into the oxide semiconductor layer again; thus, the oxide semiconductor layer 431 is obtained (see FIG. 1B).

Note that the apparatus for the heat treatment is not limited to a particular apparatus, and the apparatus may be provided with a device for heating an object to be processed by heat radiation or heat conduction from a heating element such as a resistance heating element. For example, an electric furnace, or a rapid thermal annealing (RTA) apparatus such as a gas rapid thermal annealing (GRTA) apparatus or a lamp rapid thermal annealing (LRTA) apparatus can be used. An LRTA apparatus is an apparatus for heating an object to be processed by radiation of light (electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas. As the gas, an inert gas which does not react with an object to be processed by heat treatment, such as nitrogen or a rare gas such as argon is used.

For example, as the first heat treatment, GRTA may be performed in the following manner. The substrate is transferred into an inert gas heated at high temperatures of 650° C. to 700° C., and after heating for one minute to 10 minutes, the substrate may be transferred and taken out of the inert gas heated at high temperatures. With GRTA, high-temperature heat treatment for a short period of time can be achieved.

Note that in the first heat treatment, it is preferable that water, hydrogen, and the like be not contained in a nitrogen atmosphere or a rare gas atmosphere such as helium, neon, or argon. Alternatively, it is preferable that nitrogen or a rare gas such as helium, neon, or argon introduced into an apparatus for heat treatment have purity of 6N (99.9999%) or more, preferably, 7N (99.99999%) or more (that is, an impurity concentration be set to 1 ppm or lower, preferably, 0.1 ppm or lower).

Further, depending on the condition of the first heat treatment or a material for the oxide semiconductor layer, the oxide semiconductor layer might be crystallized and changed to a microcrystalline film or a polycrystalline film. For example, the oxide semiconductor layer may crystallize to become a microcrystalline oxide semiconductor film having a degree of crystallization of 90% or more, or 80% or more. Alternatively, depending on the condition of the first heat treatment and the material for the oxide semiconductor layer, the oxide semiconductor layer might become an amorphous oxide semiconductor film containing no crystalline component. Further alternatively, depending on the condition of the first heat treatment or the material for the oxide semiconductor layer, the oxide semiconductor film might become an oxide semiconductor film in which a microcrystalline portion (a grain diameter of 1 nm to 20 nm inclusive) is mixed into an amorphous oxide semiconductor. Further, when high-temperature heating is performed with the use of RTA (GRTA or LRTA), in the vicinity of a surface of the oxide semiconductor film, needle-like crystals might be generated in a direction perpendicular to the surface (c-axis orientation). In this case, an oxide semiconductor film is formed having a portion with a high degree of crystallinity in the vicinity of its surface and the other portion in which a microcrystalline portion (a grain diameter of 1 nm to 20 nm inclusive) is mixed into an amorphous oxide semiconductor, depending on the condition of the heating with the use of RTA, the material for the oxide semiconductor film, and the film thickness of the oxide semiconductor film.

Alternatively, the first heat treatment for the oxide semiconductor layer can be performed on the oxide semiconductor film 430 before it is processed into the island-like oxide semiconductor layer. In that case, after the first heat treatment, the substrate is taken out of the heating apparatus and a photolithography step is performed.

Next, although not illustrated here, a contact hole reaching the gate electrode layer 411 is formed in the gate insulating layer 402b by a fourth photolithography step. In the contact hole, the gate electrode layer 411 is electrically connected to a terminal electrode and a lead wiring which are to be provided in the upper portion later. Further, the contact hole may be formed, without the fourth photolithography step, in the same step as another contact hole which is to be formed later, in order to reduce the number of masks.

Next, after a metal conductive film is formed over the gate insulating layer 402b and the oxide semiconductor layer 431 by a sputtering method or the like, a fifth photolithography step is performed. A resist mask is formed, and the metal conductive film is selectively etched, so that metal electrode layers are formed. In this embodiment, the metal electrode film is etched so that end portions of the metal electrode layer is located above the oxide semiconductor layer overlapping with an opening region in the insulating layer 402a. In the opening region, an end of the metal electrode layer serving as a source electrode layer and another end serving as a drain electrode layer are provided, and a distance between the ends is defined as a channel length L.

Examples of the material for the metal conductive film are an element selected from Al, Cr, Cu, Ta, Ti, Mo, and W; an alloy containing any of these elements as a component; and an alloy containing any of these elements in combination.

The metal conductive film preferably has a three-layer structure in which an aluminum layer is stacked over a titanium layer and a titanium layer is stacked over the aluminum layer, or a three-layer structure in which an aluminum layer is stacked over a molybdenum layer and a molybdenum layer is stacked over the aluminum layer. Alternatively, the metal conductive film can have a two-layer structure in which an aluminum layer and a tungsten layer are stacked, a two-layer structure in which a copper layer and a tungsten layer are stacked, or a two-layer structure in which an aluminum layer and a molybdenum layer are stacked. Needless to say, the metal conductive film may have a single-layer structure or a stacked-layer structure including four or more layers.

Then, the resist mask is removed, and a sixth photolithography step is performed. A resist mask is formed, and selective etching is performed, so that the source electrode layer 415a and the drain electrode layer 415b are formed. Then, the resist mask is removed. Note that, in the sixth photolithography step, only part of the oxide semiconductor layer 431 is etched, whereby an oxide semiconductor layer having a groove (a depressed portion) is formed in some cases. Further, the resist mask for forming the source electrode layer 415a and the drain electrode layer 415b may be formed by an inkjet method. A photomask is not used when the resist mask is formed by an inkjet method, which results in reducing manufacturing costs.

In order to reduce the number of photomasks used in a photolithography step and reduce the number of photolithography steps, an etching step may be performed with the use of a multi-tone mask which is a light-exposure mask through which light is transmitted to have a plurality of intensities. Since a resist mask formed with the use of a multi-tone mask has a plurality of film thicknesses and further can be changed in shape by performing etching on the resist mask, the resist mask can be used in a plurality of etching steps for processing into different patterns. Therefore, a resist mask corresponding to at least two kinds or more of different patterns can be formed by one multi-tone mask. Thus, the number of light-exposure masks can be reduced and the number of corresponding photolithography steps can be also reduced, whereby simplification of a process can be realized.

Next, the oxide insulating layer 416 serving as a protective insulating film is formed in contact with part of the oxide semiconductor layer.

The oxide insulating layer 416, which has a thickness of at least 1 nm or more, can be formed as appropriate using a sputtering method or the like, that is a method with which impurities such as water and hydrogen are not mixed into the oxide insulating layer 416. In this embodiment, a silicon oxide film is formed to a thickness of 300 nm as the oxide insulating layer 416 by a sputtering method. The substrate temperature in film formation may be higher than or equal to room temperature and lower than or equal to 300° C. and in this embodiment, is 100° C. The formation of the silicon oxide film by a sputtering method can be performed in a rare gas (typically argon) atmosphere, an oxygen atmosphere, or an atmosphere of a rare gas (typically argon) and oxygen. Moreover, a silicon oxide target or a silicon target can be used as a target. For example, with the use of a silicon target, silicon oxide can be formed by a sputtering method under an atmosphere of oxygen and nitrogen. As the oxide insulating layer 416 which is formed in contact with the oxide semiconductor layer whose resistance is reduced, an inorganic insulating film which does not include impurities such as moisture, a hydrogen ion, and OH⁻ and blocks entry of these from the outside is used. Typically, a silicon oxide film, a silicon nitride oxide film, an aluminum oxide film, an aluminum oxynitride film, or the like is used. Further, a protective insulating layer such as a silicon nitride film or an aluminum nitride film may be formed over the oxide insulating layer 416.

Further, preheat treatment is preferably performed before the oxide insulating layer 416 is formed, in order to remove water or hydrogen which remains on an inner wall of a sputtering apparatus, on a surface of the target, or inside a target material. After the preheat treatment, the substrate or the sputtering apparatus is cooled. Then, an oxide insulating layer is formed without exposure to the air. In this case, not water but oil or the like is preferably used as a coolant for the target. Although a certain level of effect can be obtained when introduction and exhaust of nitrogen are repeated without heating, it is preferable to perform the treatment with the inside of the film formation chamber heated.

Further, after the film formation of the oxide insulating layer 416, a silicon nitride film may be stacked thereover by a sputtering method without exposure to the air.

Next, second heat treatment (preferably 100° C. to 400° C. inclusive, for example, 250° C. to 350° C. inclusive, for one hour to 30 hours) is performed under an inert gas atmosphere or an oxygen gas atmosphere. For example, the second heat treatment is performed at 150° C. for 10 hours under a nitrogen atmosphere. Through the second heat treatment, part of the oxide semiconductor layer (a channel formation region) is heated while being in contact with the oxide insulating layer 416.

Through the above-described steps, the oxide semiconductor film formed is reduced in resistance by heat treatment for dehydration or dehydrogenation, and then, part of the oxide semiconductor film is selectively made to be in an oxygen-excess state. As a result, the channel formation region 414c overlapping with the gate electrode layer 411 becomes intrinsic, and the high-resistance source region 414a which overlaps with the source electrode layer 415a and the high-resistance drain region 414b which overlaps with the drain electrode layer 415b are formed in a self-aligned manner. Through the above-described steps, the thin film transistor 410 is formed.

The oxide semiconductor preferably includes In, and further preferably includes In and Ga. Dehydration or dehydrogenation is effective in forming an i-type (intrinsic) oxide semiconductor layer.

By the formation of the high-resistance drain region 414b (or the high-resistance source region 414a) in part of the oxide semiconductor layer, which overlaps with the drain electrode layer 415b (and the source electrode layer 415a), reliability of the thin film transistor can be improved. Specifically, when the high-resistance drain region 414b is formed, a transistor can have a structure in which conductivity is gradually changed from the drain electrode layer to the high-resistance drain region 414b and the channel formation region. Thus, in the case where operation is performed with the drain electrode layer 415b connected to a wiring for supplying a high power supply potential VDD, the high-resistance drain region serves as a buffer, and thus local concentration of an electric field is not apt to occur even if high voltage is applied between the gate electrode layer 411 and the drain electrode layer 415b, which leads to an increase in the withstand voltage of the transistor.

A thick insulating layer (a stack including a spacer insulating layer and a gate insulating layer) is located on the periphery (including a side surface) of a gate electrode layer. With such a structure, the parasitic capacitance of the thin film transistor 410 illustrated in FIG. 1D, which is formed between the gate electrode layer 411 and the drain electrode layer 415b, can be reduced. Particularly in the case where the gate electrode layer is thick and the gate insulating layer is thin on the periphery (including the side surface) of the gate electrode layer, the gate insulating layer formed on the side surface of the gate electrode layer is likely to have a thickness smaller than the gate insulating layer formed over a top surface of the gate electrode layer, resulting in an increase in parasitic capacitance. Therefore, it can be said that the structure of the thin film transistor 410 illustrated in FIG. 1D is effective especially in the case where the gate electrode layer is formed to be thick and the gate insulating layer is formed to be thin. Further, only the gate insulating layer 402b with a small thickness is provided between the channel formation region and the gate electrode layer; thus, the electric characteristics can be improved.

### Embodiment 2

In this embodiment, an example in which a pixel portion and a driver circuit are formed over one substrate by using the structure of the thin film transistor described in Embodiment 1 to manufacture an active matrix light-emitting display device is described.

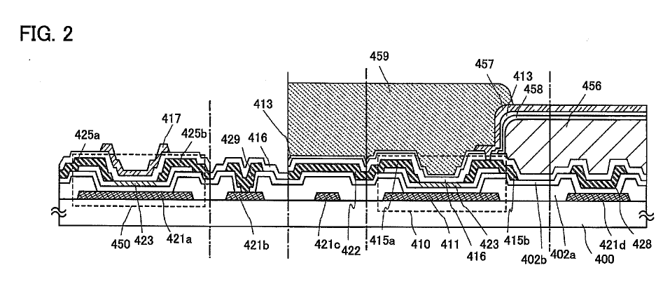

FIG. 2 is a cross-sectional view illustrating a substrate over which an EL layer is to be formed over a first electrode (pixel electrode). Note that components in FIG. 2 that are common to those in FIG. 1D are denoted by the same reference numerals.

In FIG. 2, a driving TFT which is electrically connected to a first electrode 457 is the bottom-gate thin film transistor 410 in a pixel portion, which can be manufactured in accordance with Embodiment 1.

Note that in the case where a light-emitting device is formed, a plurality of thin film transistors is provided in one pixel, and a connection portion which connects the gate electrode layer of one thin film transistor to the drain electrode layer of the other thin film transistor is provided. A connection electrode layer 429 is formed using the same material and the same step as the drain electrode layer 415b of the thin film transistor, after a contact hole is formed by selectively etching the gate insulating layer 402b. Note that the connection electrode layer 429 is electrically connected to a gate electrode layer 421b.

After the oxide insulating layer 416 is formed in accordance with Embodiment 1, a green color filter layer 456, a blue color filter layer, and a red color filter layer are sequentially formed. Each color filter layer is formed by a printing method; an inkjet method, an etching method using a photolithography technique, or the like. By providing the color filter layer, alignment of the color filter layer and a light-emitting region of a light-emitting element can be performed without depending on the alignment accuracy of a sealing substrate.

Next, an overcoat layer 458 which covers the green color filter layer 456, the blue color filter layer, and the red color filter layer is formed. The overcoat layer 458 is formed using a light-transmitting resin.

Here, an example in which full color display is performed using three colors of RGB is shown; however, the present invention is not particularly limited thereto, and full color display may be performed using four colors of RGBW.

Next, a protective insulating layer 413 covering the overcoat layer 458 and the oxide insulating layer 416 is formed. As the protective insulating layer 413, an inorganic insulating film is used. Specifically, a silicon nitride film, an aluminum nitride film, a silicon nitride oxide film, aluminum oxynitride, or the like is used. It is preferable that the protective insulating layer 413 be an insulating film having the same component as that of the oxide insulating layer 416 because they can thus be etched by one process at the time of formation of a contact hole later.

Next, the protective insulating layer 413 and the oxide insulating layer 416 are selectively etched by a photolithography step, so that a contact hole reaching the drain electrode layer 415b is formed. In addition, by this photolithography step, the protective insulating layer 413 and the oxide insulating layer 416 in a terminal portion are selectively etched to expose part of a terminal electrode. Further, in order to connect a second electrode of a light-emitting element formed later to a common potential line, a contact hole reaching the common potential line is also formed.

Next, a light-transmitting conductive film is formed, and by a photolithography step, the first electrode 457 which is electrically connected to the drain electrode layer 415b is formed.

Next, a partition wall 459 is formed to cover the periphery of the first electrode 457. The partition wall 459 is formed using an organic resin film of polyimide, acrylic, polyamide, epoxy, or the like, an inorganic insulating film, or organic polysiloxane. It is particularly preferable that the partition wall 459 be formed using a photosensitive resin material to have an opening over the first electrode 457 so that a sidewall of the opening is formed as an inclined surface with continuous curvature. In the case where a photosensitive resin material is used as the partition wall 459, a step of forming a resist mask can be omitted.

Through the above steps, the state of the substrate shown in FIG. 2 can be obtained. After the above steps, an EL layer is formed over the first electrode 457, and a second electrode is formed over the EL layer, whereby a light-emitting element is formed. The second electrode is electrically connected to the common potential line.

Further, as shown in FIG. 2, in a capacitor portion, a capacitor wiring layer 421d is provided and the insulating layer 402a covering the periphery of the capacitor wiring layer 421d is formed. The capacitor includes the capacitor wiring layer 421d, a capacitor electrode layer 428, and the gate insulating layer 402b serving as a dielectric. In a light-emitting device, the capacitor wiring layer 421d is part of a power supply line, and the capacitor electrode layer 428 is part of the gate electrode layer of the driving TFT.

In a wiring intersection portion, as illustrated in FIG. 2, the insulating layer 402a and the gate insulating layer 402b are stacked between a gate wiring layer 421c and a source wiring layer 422 in order to reduce the parasitic capacitance.

In FIG. 2, a TFT provided in the driver circuit is a bottom-gate thin film transistor 450, which can be manufactured in accordance with Embodiment 1 in this embodiment. Note that a conductive layer 417 is provided over an oxide semiconductor layer of the thin film transistor 450 in the driver circuit; however, it is acceptable that the conductive layer 417 is not provided if not needed. The conductive layer 417 can be formed using the same material and the same step as the first electrode 457.

With the use of the conductive layer 417 overlapping with a channel formation region 423 of the oxide semiconductor layer, in a bias-temperature stress test (hereinafter, referred to as a BT test) for examining the reliability of a thin film transistor, the amount of change in the threshold voltage of the thin film transistor 450 before and after the BT test can be reduced. The potential of the conductive layer 417 may be the same or different from that of the gate electrode layer 421a. The conductive layer 417 can also function as a second gate electrode layer. Alternatively, the potential of the conductive layer 417 may be GND or 0 V, or the conductive layer 417 may be in a floating state.

Since a thin film transistor is easily broken due to static electricity or the like, a protective circuit is preferably provided over the same substrate as the pixel portion or the drive circuit. The protective circuit is preferably formed with a non-linear element including an oxide semiconductor layer. For example, a protective circuit is provided between the pixel portion, and a scan line input terminal and a signal line input terminal. In this embodiment, a plurality of protective circuits is provided in order to prevent breakage of the a pixel transistor and the like which can be caused when a surge voltage due to static electricity or the like is applied to a scan line, a signal line, and a capacitor bus line. Therefore, the protective circuit is formed so that charge is released to a common wiring when surge voltage is applied to the protective circuit. Further, the protective circuit includes non-linear elements arranged in parallel to each other with the scan line therebetween. The non-linear element includes a two-terminal element such as a diode or a three-terminal element such as a transistor. For example, the non-linear element can be formed through the same step as the thin film transistor 410 in the pixel portion, and can be made to have the same properties as a diode by connecting a gate terminal to a drain terminal of the non-linear element

This embodiment can be freely combined with Embodiment 1.

### Embodiment 3

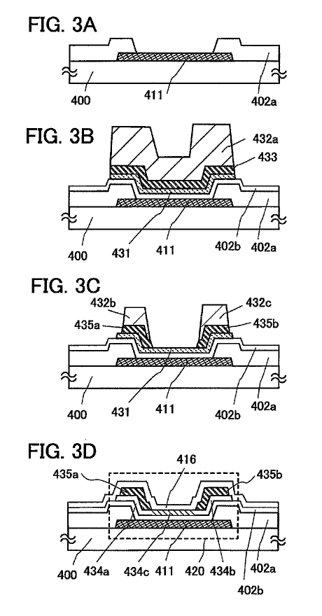

In this embodiment, an example in which a process is partly different from that described in Embodiment 1 is described with reference to FIGS. 3A to 3D. In this embodiment, an etching step is performed using a mask layer formed with the use of a multi-tone mask which is a light-exposure mask through which light is transmitted to have a plurality of intensities. Thus, the total number of photomasks is reduced. Note that components in FIGS. 3A to 3D that are common to those in FIGS. 1A to 1D are denoted by the same reference numerals.

First, in accordance with Embodiment 1, the conductive film is formed over the substrate 400; the gate electrode layer 411 is formed after that; and the insulating layer 402a is formed over the gate electrode layer 411. Thus, a state illustrated in FIG. 3A is obtained. Note that FIG. 3A is the same as FIG. 1A.

Then, in accordance with Embodiment 1, the gate insulating layer 402b is formed. After the formation of the gate insulating layer 402b, the oxide semiconductor film is formed to a thickness of 2 nm to 200 nm inclusive over the gate insulating layer 402b without exposure to the air. In this embodiment, the oxide semiconductor film is formed to a thickness of 20 nm in an oxygen atmosphere, an argon atmosphere, or an atmosphere containing argon and oxygen under a condition that a target is a target for film formation of an oxide semiconductor containing In, Ga, and Zn (a target for film formation of an In—Ga—Zn—O-based oxide semiconductor (In₂O₃:Ga₂O₃:ZnO=1:1:1), the distance between the substrate and the target is 170 mm, pressure is 0.4 Pa, and a direct current (DC) power source is 0.5 kW.

Further, preheat treatment is preferably performed before the oxide semiconductor film is formed, in order to remove moisture or hydrogen which remains on an inner wall of a sputtering apparatus, on a surface of the target, or inside a target material.

Next, the oxide semiconductor film is subjected to dehydration or dehydrogenation. The temperature of the first heat treatment for dehydration or dehydrogenation is higher than or equal to 400° C. and lower than or equal to 750° C., preferably higher than or equal to 400° C. and lower than the strain point of the substrate. In this embodiment, heating is performed at 650° C. for six minutes with the use of a GRTA apparatus which performs heat treatment using a high-temperature nitrogen gas.

Next, the metal conductive film is formed over the oxide semiconductor film, and then, a resist mask 432a is formed over the metal conductive film. In this embodiment, an example in which light exposure is performed using a multi-tone mask to form the resist mask 432a is described. First, a resist is formed in order to form the resist mask 432a. As the resist, a positive type resist or a negative type resist can be used. Here, a positive type resist is used. The resist may be formed by a spin coating method or may be selectively formed by an inkjet method. When the resist is selectively formed by an inkjet method, a resist can be prevented from being formed in an unintended portion, which results in reducing waste of the material.

A multi-tone mask can achieve three levels of light exposure to obtain an exposed portion, a half-exposed portion, and an unexposed portion. A multi-tone mask is a mask through which light is transmitted to have a plurality of intensities. One-time light exposure and development step can form a resist mask with regions of plural thicknesses (typically, two kinds of thicknesses). Accordingly, by using a multi-tone mask, the number of photomasks can be reduced.

As typical examples of a multi-tone mask, there are a gray-tone mask, a half-tone mask, and the like. A gray-tone mask includes a diffraction grating having regularly-arranged slits, dots, or meshes form, or irregularly-arranged slits, dots, or meshes, and a light-shielding portion. A half-tone mask includes a semi-transmissive portion formed using MoSiN, MoSi, MoSiO, MoSiON, CrSi, or the like, and a light-shielding portion.

After the light exposure using the multi-tone mask is performed, development is carried out, whereby the resist mask 432a having regions with different thicknesses can be formed as illustrated in FIG. 3B.

Next, a first etching step is performed using the resist mask 432a, so that the oxide semiconductor film and the metal conductive film are etched into island shapes. Thus, the oxide semiconductor layer 431 and a metal conductive layer 433 can be formed (see FIG. 3B).

Next, the resist mask 432a is subject to ashing. Consequently, the area (the volume considering three dimensions) of the resist mask is reduced and the thickness is reduced. At this time, part of the resist mask in a region with a small thickness (a region overlapping with part of the gate electrode layer 411) is removed, so that separated resist masks 432b and 432c can be formed.

The metal conductive layer 433 is etched by a second etching step with the use of the resist masks 432b and 432c; thus, a source electrode layer 435a and a drain electrode layer 435b are formed (see FIG. 3C). Note that depending on the condition of the second etching step, only part of the oxide semiconductor layer is etched, whereby an oxide semiconductor layer having a groove (a depressed portion) is formed in some cases. Further, depending on the condition of the second etching step, the oxide semiconductor layer 431 might have a region with a small thickness in the edge portion.

Next, the resist masks 432b and 432c are removed, and then, the oxide insulating layer 416 serving as a protective insulating film is formed in contact with the oxide semiconductor layer 431.

Further, preheat treatment is preferably performed before the oxide insulating layer 416 is formed, in order to remove moisture or hydrogen which remains on an inner wall of a sputtering apparatus, on a surface of the target, or inside a target material.

Next, second heat treatment (preferably 100° C. to 400° C. inclusive, for example, 250° C. to 350° C. inclusive, for one hour to 30 hours) is performed under an inert gas atmosphere or an oxygen gas atmosphere. For example, the second heat treatment is performed at 150° C. for 10 hours under a nitrogen atmosphere. Through the second heat treatment, part of the oxide semiconductor layer (a channel formation region) is heated while being in contact with the oxide insulating layer 416.

Through the above-described steps, heat treatment for dehydration or dehydrogenation is performed on the oxide semiconductor film after film formation to reduce the resistance, and then, part of the oxide semiconductor film is selectively made to be in an oxygen-excess state. As a result, a channel formation region 434c overlapping with the gate electrode layer 411 becomes intrinsic, and a high-resistance source region 434a which overlaps with the source electrode layer 435a and a high-resistance drain region 434b which overlaps with the drain electrode layer 435b are formed in a self-aligned manner. Through the above-described steps, the thin film transistor 420 is formed.

A thick insulating layer (a stack including a spacer insulating layer and a gate insulating layer) is located on the periphery (including a side surface) of the gate electrode layer of the thin film transistor 420. With such a structure, the parasitic capacitance which is formed between the gate electrode layer 411 and the drain electrode layer 435b can be reduced.

Further, with the use of a multi-tone mask, the number of masks can be reduced by one as compared to Embodiment 1.

In the case where a conductive layer which is electrically connected to the drain electrode layer 435b is formed over the oxide insulating layer 416, a contact hole is formed in the oxide insulating layer 416. With the use of the mask used for the formation of this contact hole, a contact hole reaching the gate electrode layer 411 can be formed. For example, in manufacturing a liquid crystal display device, a pixel electrode layer which is electrically connected to the drain electrode layer 435b is formed, and an electrode layer (a terminal electrode, a connection electrode, or the like) which is electrically connected to the gate electrode layer 411 is formed in a photolithography step using the same mask. In this case, the number of masks can be further reduced by one as compared to Embodiment 1.

This embodiment can be freely combined with Embodiment 1 or Embodiment 2.

### Embodiment 4

In this embodiment, an example in which a pixel portion and a driver circuit are formed over one substrate by using the structure of the thin film transistor described in Embodiment 3 to manufacture an active matrix liquid crystal display device is described.

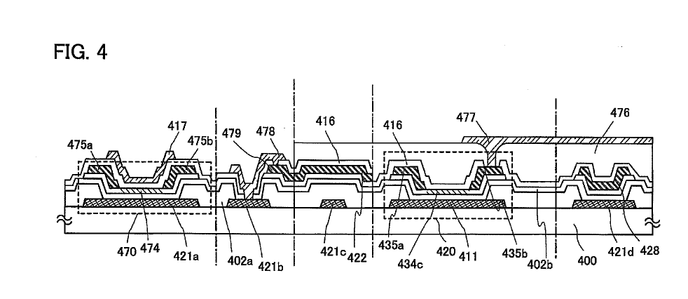

FIG. 4 is a cross-sectional view illustrating a substrate over which the pixel electrode layer is formed. Note that components in FIG. 4 that are common to those in FIG. 3D are denoted by the same reference numerals.

In FIG. 4, a driving TFT which is electrically connected to a pixel electrode layer 477 is a bottom-gate thin film transistor 420 in a pixel portion, which can be manufactured in accordance with Embodiment 3.

After the oxide insulating layer 416 is formed in accordance with Embodiment 1, the oxide insulating layer 416 is selectively etched by a photolithography step, so that a contact hole reaching the drain electrode layer 435b is formed. Further, by the photolithography step, the gate insulating layer 402b and the oxide insulating layer 416 in a connection wiring portion are selectively etched, so that part of the gate electrode layer 421b is exposed. Furthermore, by the photolithography step, the oxide insulating layer 416 is selectively etched, so that a contact hole reaching a connection electrode layer 479 in the connection wiring portion is formed.

Next, a planarization insulating layer 476 is formed over the oxide insulating layer 416. The planarization insulating layer 476 can be formed using a heat-resistant organic material, such as polyimide, acrylic, benzocyclobutene, polyamide, or epoxy. Other than such organic materials, it is also possible to use a low-dielectric constant material (a low-k material), a siloxane-based resin, PSG (phosphosilicate glass), BPSG (borophosphosilicate glass), or the like. The planarization insulating layer 476 may be formed by stacking a plurality of insulating films formed of these materials.

In the case of using a photosensitive resin material for the planarization insulating layer 476, a step of forming a resist mask can be omitted. In this embodiment, the planarization insulating layer 476 is formed using a photosensitive acrylic resin. Note that in the case where the conductive layer 417 is provided over an oxide semiconductor layer of a thin film transistor 470 in the driver circuit, the planarization insulating layer overlapping with the conductive layer 417 and the thin film transistor 470 is preferably removed.

Next, a light-transmitting conductive film is formed, and by a photolithography step, the pixel electrode layer 477 which is electrically connected to the drain electrode layer 435b is formed.

Through the above steps, the substrate illustrated in FIG. 4 can be obtained. In this embodiment, five photomasks are used for obtaining the substrate illustrated in FIG. 4. After the above steps, a counter substrate provided with a counter electrode, and the substrate illustrated in FIG. 4, are fixed together. A liquid crystal layer is provided between the substrate illustrated in FIG. 4 and the counter substrate provided with a counter electrode. Note that a common electrode to be electrically connected to the counter electrode on the counter substrate is provided over the substrate illustrated in FIG. 4, and a terminal electrode to be electrically connected to the common electrode is provided in the terminal portion. This terminal electrode is provided so that the common electrode is set to a fixed potential such as GND or 0 V.

Further, the step described in Embodiment 3 is an example of using a multi-tone mask. Thus, the oxide semiconductor layer is provided in contact with the bottom of the same wiring layer or the same electrode layer as the drain electrode layer and the source electrode layer. Note that the capacitor electrode layer 428, the source wiring layer 422, the connection electrode layer 479, a source electrode layer 475a, and a drain electrode layer 475b are formed using the same material and the same step as the drain electrode layer 435b and the source electrode layer 435a.

Further, as shown in FIG. 4, in the capacitor portion, the capacitor wiring layer 421d is provided and the insulating layer 402a covering the periphery of the capacitor wiring layer 421d is formed. The capacitance is formed with the use of the gate insulating layer 402b as a dielectric, the capacitor wiring layer 421d, and the capacitor electrode layer 428.

In the wiring intersection portion, as illustrated in FIG. 4, the insulating layer 402a and the gate insulating layer 402b are stacked between the gate wiring layer 421c and the source wiring layer 422 in order to reduce the parasitic capacitance.

In a wiring connection portion, as illustrated in FIG. 4, an electrode layer 478 in contact with the gate electrode layer 421b and the connection electrode layer 479 is provided in order to electrically connect the gate electrode layer 421b and the connection electrode layer 479. The electrode layer 478 can be formed using the same material and the same step as the pixel electrode layer 477 and the conductive layer 417.

In FIG. 4, a TFT provided in the driver circuit is a bottom-gate thin film transistor 470, which can be manufactured in accordance with Embodiment 3 in this embodiment. Although the conductive layer 417 is provided over the oxide semiconductor layer of the thin film transistor 470 in the driver circuit, it is acceptable that the conductive layer 417 is not provided if not needed. The conductive layer 417 can be formed using the same material and the same step as the pixel electrode layer 477.

With the use of the conductive layer 417 overlapping with a channel formation region 474 of the oxide semiconductor layer, in a bias-temperature stress test (hereinafter, referred to as a BT test) for examining the reliability of a thin film transistor, the amount of change in the threshold voltage of the thin film transistor 470 before and after the BT test can be reduced. The potential of the conductive layer 417 may be the same or different from that of the gate electrode layer 421a. The conductive layer 417 can also function as a second gate electrode layer. Alternatively, the potential of the conductive layer 417 may be GND or 0 V, or the conductive layer 417 may be in a floating state.

This embodiment can be freely combined with Embodiment 1 or Embodiment 3.

### Embodiment 5

Thin film transistors are manufactured, and a semiconductor device having a display function (also referred to as a display device) can be manufactured using the thin film transistors in a pixel portion and further in a driver circuit. Moreover, part of the driver circuit or the entire driver circuit, which includes a thin film transistor, can be formed over a substrate where a pixel portion is formed, whereby a system-on-panel can be obtained.

The display device includes a display element. As the display element, a liquid crystal element (also referred to as a liquid crystal display element) or a light-emitting element (also referred to as a light-emitting display element) can be used. The light-emitting element includes, in its category, an element whose luminance is controlled by a current or a voltage, and specifically includes, in its category, an inorganic electroluminescent (EL) element, an organic EL element, and the like. Furthermore, a display medium whose contrast is changed by an electric effect, such as electronic ink, can be used.

In addition, the display device includes a panel in which the display element is sealed, and a module in which an IC or the like including a controller is mounted on the panel. Furthermore, an element substrate, which corresponds to one embodiment before the display element is completed in a manufacturing process of the display device, is provided with a means for supplying current to the display element in each of a plurality of pixels. Specifically, the element substrate may be in a state in which only a pixel electrode of the display element is formed, a state in which a conductive film to be a pixel electrode is formed but is not etched yet to form the pixel electrode, or any other states.

Note that “display device” in this specification means an image display device, a display device, or a light source (including a lighting device). Further, the “display device” includes the following modules in its category: a module including a connector such as a flexible printed circuit (FPC), a tape automated bonding (TAB) tape, or a tape carrier package (TCP) attached; a module having a TAB tape or a TCP which is provided with a printed wiring board at the end thereof; and a module having an integrated circuit (IC) which is directly mounted on a display element by a chip on glass (COG) method.

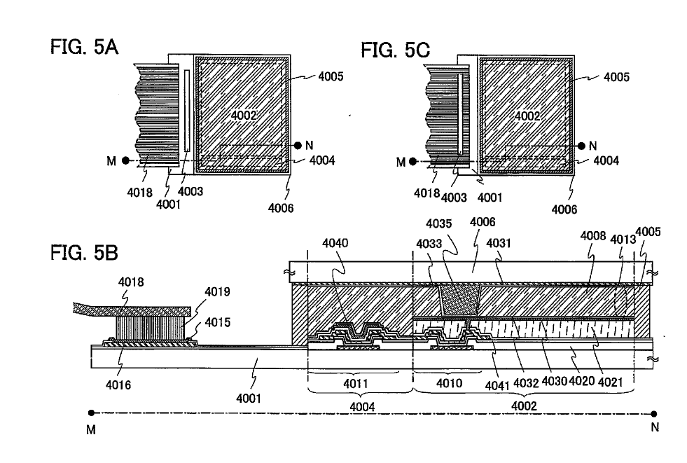

The appearance and a cross section of a liquid crystal display panel, which corresponds to one embodiment of a semiconductor device, are described with reference to FIGS. 5A to 5C. FIGS. 5A to 5C are views illustrating panels in each of which thin film transistors 4010 and 4011 and a liquid crystal element 4013 are sealed between a first substrate 4001 and a second substrate 4006 with a sealant 4005. FIG. 5B is a cross-sectional view taken along line M-N in FIG. 5A or FIG. 5C.

The sealant 4005 is provided to surround a pixel portion 4002 and a scan line driver circuit 4004 which are provided over the first substrate 4001. The second substrate 4006 is provided over the pixel portion 4002 and the scan line driver circuit 4004. Therefore, the pixel portion 4002 and the scan line driver circuit 4004 are sealed together with a liquid crystal layer 4008, by the first substrate 4001, the sealant 4005, and the second substrate 4006. A signal line driver circuit 4003 that is formed using a single crystal semiconductor film or a polycrystalline semiconductor film over a substrate separately prepared is mounted in a region that is different from the region surrounded by the sealant 4005 over the first substrate 4001.

Note that there is no particular limitation on the connection method of a driver circuit which is separately formed, and COG, wire bonding, TAB, or the like can be used. FIG. 5A illustrates an example of mounting the signal line driver circuit 4003 by a COG method, and FIG. 5C illustrates an example of mounting the signal line driver circuit 4003 by a TAB method.

The pixel portion 4002 and the scan line driver circuit 4004 over the first substrate 4001 include a plurality of thin film transistors. FIG. 5B illustrates the thin film transistor 4010 included in the pixel portion 4002 and the thin film transistor 4011 included in the scan line driver circuit 4004. Protective insulating layers 4041, 4020, and 4021 are provided over the thin film transistors 4010 and 4011.

The thin film transistor including the oxide semiconductor layer, which is described in Embodiment 1 or Embodiment 3, can be used as the thin film transistors 4010 and 4011. The thin film transistors 410 or the thin film transistor 420 which is described in Embodiment 1 or Embodiment 3 can be used as the thin film transistor 4011 for the driver circuit and the thin film transistor 4010 for the pixel. In this embodiment, the thin film transistors 4010 and 4011 are n-channel thin film transistors.

A conductive layer 4040 is provided over part of the insulating layer 4021, which overlaps with a channel formation region of an oxide semiconductor layer in the thin film transistor 4011 for the driver circuit. The conductive layer 4040 is provided at the position overlapping with the channel formation region of the oxide semiconductor layer, whereby the amount of change in threshold voltage of the thin film transistor 4011 before and after the BT test can be reduced. A potential of the conductive layer 4040 may be the same or different from that of a gate electrode layer of the thin film transistor 4011. The conductive layer 4040 can also function as a second gate electrode layer. Alternatively, the potential of the conductive layer 4040 may be GND or 0 V, or the conductive layer 4040 may be in a floating state.

A pixel electrode layer 4030 included in the liquid crystal element 4013 is electrically connected to the thin film transistor 4010. A counter electrode layer 4031 of the liquid crystal element 4013 is provided for the second substrate 4006. A portion where the pixel electrode layer 4030, the counter electrode layer 4031, and the liquid crystal layer 4008 overlap with one another corresponds to the liquid crystal element 4013. Note that the pixel electrode layer 4030 and the counter electrode layer 4031 are provided with an insulating layer 4032 and an insulating layer 4033 respectively which each function as an alignment film, and the liquid crystal layer 4008 is sandwiched between the pixel electrode layer 4030 and the counter electrode layer 4031 with the insulating layers 4032 and 4033 therebetween.

Note that a light-transmitting substrate can be used as the first substrate 4001 and the second substrate 4006; glass, ceramics, or plastics can be used. As plastics, a fiberglass-reinforced plastics (FRP) plate, a polyvinyl fluoride (PVF) film, a polyester film, or an acrylic resin film can be used.

Reference numeral 4035 denotes a columnar spacer obtained by selectively etching an insulating film and is provided to control the distance between the pixel electrode layer 4030 and the counter electrode layer 4031 (a cell gap). Alternatively, a spherical spacer may also be used. In addition, the counter electrode layer 4031 is electrically connected to a common potential line formed over the same substrate as the thin film transistor 4010. With use of the common connection portion, the counter electrode layer 4031 and the common potential line can be electrically connected to each other by conductive particles arranged between a pair of substrates. Note that the conductive particles are included in the sealant 4005.

Alternatively, liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase is generated within an only narrow range of temperature, liquid crystal composition containing a chiral agent at 5 wt % or more so as to improve the temperature range is used for the liquid crystal layer 4008. The liquid crystal composition which includes a liquid crystal showing a blue phase and a chiral agent has a short response time of 1 msec or less, has optical isotropy, which makes the alignment process unneeded, and has a small viewing angle dependence.

Note that this embodiment can also be applied to a semi-transmissive liquid crystal display device as well as a transmissive liquid crystal display device.

In the example of the liquid crystal display device, a polarizing plate is provided on the outer surface of the substrate (on the viewer side) and a coloring layer (a color filter) and an electrode layer used for a display element are sequentially provided on the inner surface of the substrate; alternatively, the polarizing plate may be provided on the inner surface of the substrate. The stacked structure of the polarizing plate and the coloring layer is not limited to this embodiment and may be set as appropriate depending on materials of the polarizing plate and the coloring layer or conditions of the manufacturing process. Further, a light-blocking film serving as a black matrix may be provided except in the display portion.

Over the thin film transistors 4010 and 4011, the protective insulating layer 4041 is formed to be in contact with the oxide semiconductor layer. The protective insulating layer 4041 can be formed using a material and a method which are similar to those of the oxide insulating layer 416 described in Embodiment 1. Here, the protective insulating layer 4041 is formed using a silicon oxide film by a sputtering method. In addition, in order to reduce the surface roughness due to the thin film transistors, the protective insulating layer 4041 is covered with the protective insulating layer 4021 which functions as a planarization insulating film.

As the insulating layer 4021, an organic material having heat resistance such as polyimide, acrylic, benzocyclobutene, polyamide, or epoxy can be used. Other than such organic materials, it is also possible to use a low-dielectric constant material (a low-k material), a siloxane-based resin, PSG (phosphosilicate glass), BPSG (borophosphosilicate glass), or the like. Note that the insulating layer 4021 may be formed by stacking a plurality of insulating films formed of these materials.

There is no particular limitation on the method for forming the insulating layer 4021, and the insulating layer 4021 can be formed, depending on the material, by a method such as a sputtering method, an SOG method, spin coating, dip coating, spray coating, or a droplet discharge method (such as an inkjet method, screen printing, offset printing, or the like), or a tool (equipment) such as a doctor knife, a roll coater, a curtain coater, or a knife coater. The baking step of the insulating layer 4021 also serves as annealing of the semiconductor layer, whereby a semiconductor device can be manufactured efficiently.

The pixel electrode layer 4030 and the counter electrode layer 4031 can be formed using a light-transmitting conductive material such as indium oxide containing a tungsten oxide, an indium zinc oxide containing a tungsten oxide, an indium oxide containing a titanium oxide, an indium tin oxide containing a titanium oxide, an indium tin oxide (hereinafter referred to as ITO), an indium zinc oxide, an indium tin oxide to which a silicon oxide is added, or the like.

Conductive compositions including a conductive high molecule (also referred to as a conductive polymer) can be used for the pixel electrode layer 4030 and the counter electrode layer 4031. The pixel electrode formed using the conductive composition preferably has a sheet resistance of less than or equal to 10000 ohms per square and a transmittance of greater than or equal to 70% at a wavelength of 550 nm. Further, the resistivity of the conductive high molecule included in the conductive composition is preferably less than or equal to 0.1 Ω·cm.

Further, a variety of signals and potentials are supplied to the signal line driver circuit 4003 which is formed separately, the scan line driver circuit 4004, or the pixel portion 4002 from an FPC 4018.

A connection terminal electrode 4015 is formed using the same conductive film as the pixel electrode layer 4030 included in the liquid crystal element 4013. A terminal electrode 4016 is formed using the same conductive film as source and drain electrode layers of the thin film transistors 4010 and 4011.

The connection terminal electrode 4015 is electrically connected to a terminal included in the FPC 4018 via an anisotropic conductive film 4019.

FIGS. 5A to 5C illustrate an example in which the signal line driver circuit 4003 is formed separately and mounted on the first substrate 4001; however, an embodiment of the present invention is not limited to this structure. The scan line driver circuit may be separately formed and then mounted, or only part of the signal line driver circuit or part of the scan line driver circuit may be separately formed and then mounted.

For the liquid crystal display module, a twisted nematic (TN) mode, an in-plane-switching (IPS) mode, a fringe field switching (FFS) mode, a multi-domain vertical alignment (MVA) mode, a patterned vertical alignment (PVA) mode, an axially symmetric aligned micro-cell (ASM) mode, an optical compensated birefringence (OCB) mode, a ferroelectric liquid crystal (FLC) mode, an antiferroelectric liquid crystal (AFLC) mode, or the like can be used.

An example of a VA liquid crystal display device is described below.

The VA liquid crystal display device has a kind of form in which alignment of liquid crystal molecules of a liquid crystal display panel is controlled. In the VA liquid crystal display device, liquid crystal molecules are aligned in a vertical direction with respect to a panel surface when no voltage is applied. In this embodiment, in particular, a pixel is divided into some regions (subpixels), and molecules are aligned in different directions in their respective regions. This is referred to as multi-domain or multi-domain design. Hereinafter, a liquid crystal display device of multi-domain design is described.

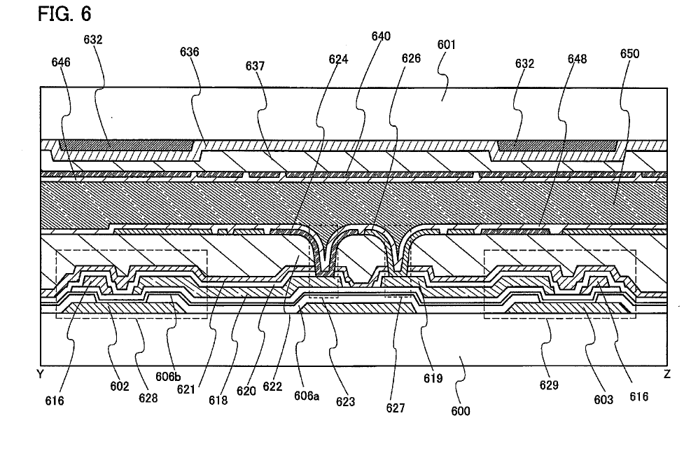

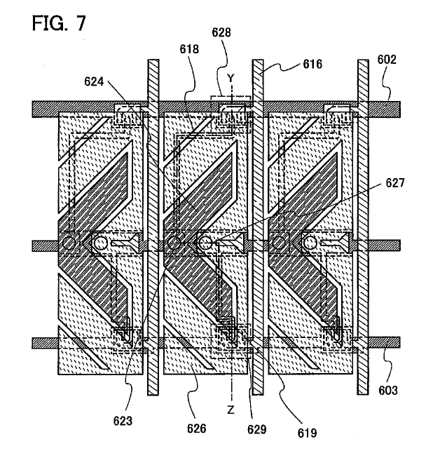

FIG. 6 and FIG. 7 each show a pixel structure of a VA liquid crystal display panel. FIG. 7 is a plan view of a substrate 600. FIG. 6 illustrates a cross-sectional structure taken along line Y-Z in FIG. 7. Description below will be given with reference to FIG. 6 and FIG. 7.

In this pixel structure, a plurality of pixel electrodes is provided in one pixel, and a TFT is connected to each pixel electrode. The plurality of TFTs is constructed so as to be driven by different gate signals. That is, a pixel of multi-domain design has a structure in which a signal applied to each of the pixel electrodes is independently controlled.

In a contact hole 623, a pixel electrode 624 is connected to a TFT 628 through a wiring 618. Further, a pixel electrode 626 is connected to a TFT 629 through a wiring 619, in a contact hole 627 provided in an insulating layer 620, a protective insulating layer 621 covering the insulating layer 620, and an insulating layer 622 covering the protective insulating layer 621. A gate wiring 602 of the TFT 628 is separated from a gate wiring 603 of the TFT 629 so that different gate signals can be supplied thereto. On the other hand, a wiring 616 serving as a data line is shared by the TFTs 628 and 629. The thin film transistor described in Embodiment 1 or Embodiment 3 can be used as appropriate for the TFTs 628 and 629.

An insulating layer 606a is formed using a silicon oxide film by a sputtering method, and a gate insulating layer 606b is formed using a silicon oxide film by a PCVD method. The insulating layer 620 in contact with the wiring 618 and the oxide semiconductor layer is formed using a silicon oxide film by a sputtering method, and the protective insulating layer 621 over the insulating layer 620 is formed using a silicon oxide film formed by a sputtering method. The pixel electrode 624 is electrically connected to the wiring 618, in the contact hole 623 provided in the insulating layer 620, the protective insulating layer 621 covering the insulating layer 620, and the insulating layer 622 covering the protective insulating layer 621.

Further, a storage capacitor is formed with the use of a capacitor wiring 690, a stacked layer of the insulating layer 606a and the gate insulating layer 606b as a dielectric, and the pixel electrode or a capacitor electrode electrically connected to the pixel electrode.

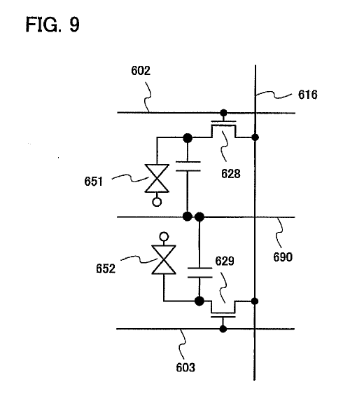

The shape of the pixel electrode 624 is different from that of the pixel electrode 626, and the pixel electrodes are separated by slits. The pixel electrode 626 surrounds the pixel electrode 624, which has a V-shape. The TFTs 628 and 629 make the timing of applying voltages to the pixel electrodes 624 and 626 different from each other, thereby controlling alignment of liquid crystals. FIG. 9 illustrates an equivalent circuit of this pixel structure. The TFT 628 is connected to the gate wiring 602, and the TFT 629 is connected to the gate wiring 603. If different gate signals are supplied to the gate wirings 602 and 603, operation timing of the TFTs 628 and 629 can be different.

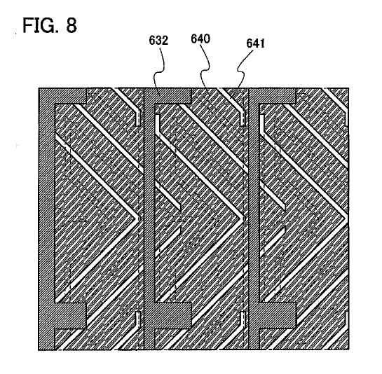

A counter substrate 601 is provided with a light blocking film 632, a second coloring film 636, and a counter electrode 640. The planarization film 637, which is also referred to as an overcoat film, is formed between the second color film 636 and the counter electrode 640 to prevent alignment disorder of liquid crystal. FIG. 8 shows the structure of the counter substrate side. The counter electrode 640 is shared by plural pixels, and slits 641 are formed in the counter electrode 640. The slits 641 and slits on the pixel electrode 624 and 626 sides are alternately arranged with each other so that an oblique electric field is effectively generated, whereby the alignment of the liquid crystal can be controlled. Accordingly, the orientation of the liquid crystals can be varied in different places, so that the viewing angle is widened.

The pixel electrode 624, the liquid crystal layer 650, and the counter electrode 640 overlap with each other, so that a first liquid crystal element is formed. Further, the pixel electrode 626, the liquid crystal layer 650, and the counter electrode 640 overlap with each other, so that a second liquid crystal element is formed. The pixel structure of this embodiment is a multi-domain structure in which the first liquid crystal element and the second liquid crystal element are included in one pixel.

This embodiment can be freely combined with any of the structures described in any one of Embodiments 1 to 3 as appropriate.

### Embodiment 6

In this embodiment, an example of electronic paper will be described as a semiconductor device which is an embodiment of the present invention.

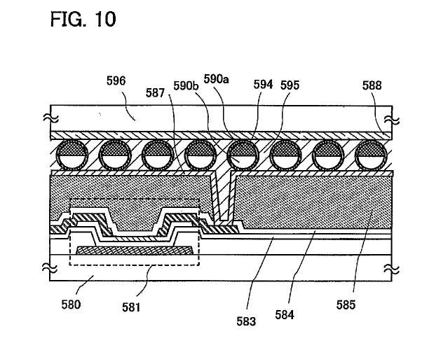

FIG. 10 illustrates active matrix electronic paper as an example of a semiconductor device to which an embodiment of the present invention is applied. A thin film transistor 581 used for the semiconductor device can be manufactured in a manner similar to the thin film transistor 410 described in Embodiment 1. The thin film transistor 581 is a thin film transistor whose parasitic capacitance is reduced, in which a thin insulating layer 583 is provided as a gate insulating layer; an end portion of a gate electrode layer is covered with a thick insulating layer; and an oxide semiconductor layer is covered with an oxide insulating layer 584.

The electronic paper in FIG. 10 is an example of a display device in which a twisting ball display system is employed. The twisting ball display system refers to a method in which spherical particles each colored in black and white are arranged between a first electrode layer and a second electrode layer which are electrode layers used for a display element, and a potential difference is generated between the first electrode layer and the second electrode layer to control orientation of the spherical particles, so that display is performed.

The thin film transistor 581 provided over a substrate 580 is a bottom-gate thin film transistor. A source electrode layer or a drain electrode layer of the thin film transistor 581 is electrically connected to a first electrode layer 587 in an opening formed in the oxide insulating layer 584. Between the first electrode layer 587 and the second electrode layer 588, spherical particles 589 are provided Each spherical particle 589 includes a black region 590a and a white region 590b, and a cavity 594 filled with liquid around the black region 590a and the white region 590b. The circumference of the spherical particle 589 is filled with filler 595 such as a resin. In this embodiment, the first electrode layer 587 corresponds to a pixel electrode and the second electrode layer 588 provided for a counter substrate 596 corresponds to a common electrode.

Further, instead of the twisting ball, an electrophoretic element can also be used. A microcapsule having a diameter of about 10 μm to 200 μm in which transparent liquid, positively charged white microparticles, and negatively charged black microparticles are encapsulated, is used. In the microcapsule provided between the first electrode layer and the second electrode layer, when an electric field is applied by the first electrode layer and the second electrode layer, the white microparticles and the black microparticles move to opposite directions to each other, so that white or black can be displayed. A display element using this principle is an electrophoretic display element and is generally called electronic paper. The electrophoretic display element has higher reflectance than a liquid crystal display element, and thus, an auxiliary light is unnecessary, power consumption is low, and a display portion can be recognized in a dim place. In addition, even when power is not supplied to the display portion, an image which has been displayed once can be maintained. Accordingly, a displayed image can be stored even if a semiconductor device having a display function (which may be referred to simply as a display device or a semiconductor device provided with a display device) is distanced from an electric wave source.

Through the above steps, highly reliable electronic paper consuming low power can be manufactured as a semiconductor device.

This embodiment can be implemented in appropriate combination with the thin film transistor described in Embodiment 1 or Embodiment 3.

### Embodiment 7

In this embodiment, an example of manufacturing an active matrix light-emitting display device using the plurality of thin film transistors described in Embodiment 1 and a light-emitting element using electroluminescence will be described.

Light-emitting elements utilizing electroluminescence are classified according to whether a light-emitting material is an organic compound or an inorganic compound. In general, the former is referred to as an organic EL element, and the latter is referred to as an inorganic EL element.

In an organic EL element, by application of voltage to a light-emitting element, electrons and holes are separately injected from a pair of electrodes into a layer containing a light-emitting organic compound, and current flows. Then, the carriers (electrons and holes) are recombined, so that light is emitted. Owing to such a mechanism, this light-emitting element is referred to as a current-excitation light-emitting element.

The inorganic EL elements are classified according to their element structures into a dispersion-type inorganic EL element and a thin-film inorganic EL element. A dispersion-type inorganic EL element has a light-emitting layer where particles of a light-emitting material are dispersed in a binder, and its light emission mechanism is donor-acceptor recombination type light emission that utilizes a donor level and an acceptor level. A thin-film inorganic EL element has a structure where a light-emitting layer is sandwiched between dielectric layers, which are further sandwiched between electrodes, and its light emission mechanism is localized type light emission that utilizes inner-shell electron transition of metal ions. Note that an example of an organic EL element as a light-emitting element is described here.

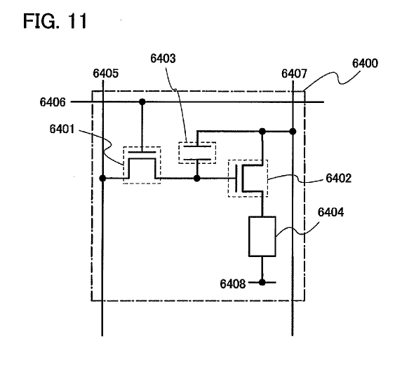

FIG. 11 illustrates an example of a pixel structure to which digital time grayscale driving can be applied, as an example of a semiconductor device.

A structure and operation of a pixel to which digital time grayscale driving can be applied are described. Here, one pixel includes two n-channel transistors each of which includes an oxide semiconductor layer as a channel formation region.

A pixel 6400 includes a switching transistor 6401, a transistor 6402 for driving a light-emitting element, a light-emitting element 6404, and a capacitor 6403. A gate of the switching transistor 6401 is connected to a scan line 6406, a first electrode (one of a source electrode and a drain electrode) of the switching transistor 6401 is connected to a signal line 6405, and a second electrode (the other of the source electrode and the drain electrode) of the switching transistor 6401 is connected to a gate of the transistor 6402 for driving the light-emitting element. The gate of the transistor 6402 for driving the light-emitting element is connected to a power supply line 6407 through the capacitor 6403, a first electrode of the transistor 6402 for driving the light-emitting element is connected to the power supply line 6407, and a second electrode of the transistor 6402 for driving the light-emitting element is connected to a first electrode (pixel electrode) of the light-emitting element 6404. A second electrode of the light-emitting element 6404 corresponds to a common electrode 6408. The common electrode 6408 is electrically connected to a common potential line provided over the same substrate as the common electrode 6408.

The second electrode (common electrode 6408) of the light-emitting element 6404 is set to a low power supply potential. Note that the low power supply potential is a potential satisfying the low power supply potential<a high power supply potential with reference to the high power supply potential that is set to the power supply line 6407. As the low power supply potential, GND, 0 V, or the like may be employed, for example. A potential difference between the high power supply potential and the low power supply potential is applied to the light-emitting element 6404 and current is supplied to the light-emitting element 6404, so that the light-emitting element 6404 emits light. Here, in order to make the light-emitting element 6404 emit light, each potential is set so that the potential difference between the high power supply potential and the low power supply potential is a forward threshold voltage or higher of the light-emitting element 6404.

When the gate capacitance of the transistor 6402 for driving the light-emitting element is used as a substitute for the capacitor 6403, the capacitor 6403 can be omitted. The gate capacitance of the transistor 6402 for driving the light-emitting element may be formed between a channel region and a gate electrode.

Here, in the case of using a voltage-input voltage driving method, a video signal is input to the gate of the transistor 6402 for driving the light-emitting element to make the transistor 6402 for driving the light-emitting element completely turn on or off. That is, the transistor 6402 for driving the light-emitting element operates in a linear region. Since the transistor 6402 for driving the light-emitting element operates in a linear region, voltage higher than the voltage of the power supply line 6407 is applied to the gate of the transistor 6402 for driving the light-emitting element. Note that a voltage greater than or equal to (power supply line voltage+Vₜₕ of the transistor 6402 for driving the light-emitting element) is applied to the signal line 6405.

Further, in the case of using analog grayscale driving instead of the digital time ratio grayscale driving, the pixel structure the same as that of FIG. 11 can be employed by inputting signals in a different way.

In the case of using the analog grayscale method, a voltage greater than or equal to (forward voltage of the light-emitting element 6404+Vₜₕ of the transistor 6402 for driving the light-emitting element) is applied to the gate of the transistor 6402 for driving the light-emitting element. The forward voltage of the light-emitting element 6404 indicates a voltage at which a desired luminance is obtained, and includes at least forward threshold voltage. By inputting a video signal to enable the transistor 6402 for driving the light-emitting element to operate in a saturation region, current can be supplied to the light-emitting element 6404. In order that the transistor 6402 for driving the light-emitting element can operate in the saturation region, the potential of the power supply line 6407 is higher than a gate potential of the transistor 6402 for driving the light-emitting element. When an analog video signal is used, it is possible to feed current to the light-emitting element 6404 in accordance with the video signal and perform analog grayscale driving.

Note that the pixel structure illustrated in FIG. 11 is not limited thereto. For example, a switch, a resistor, a capacitor, a transistor, a logic circuit, or the like may be added to the pixel shown in FIG. 11.

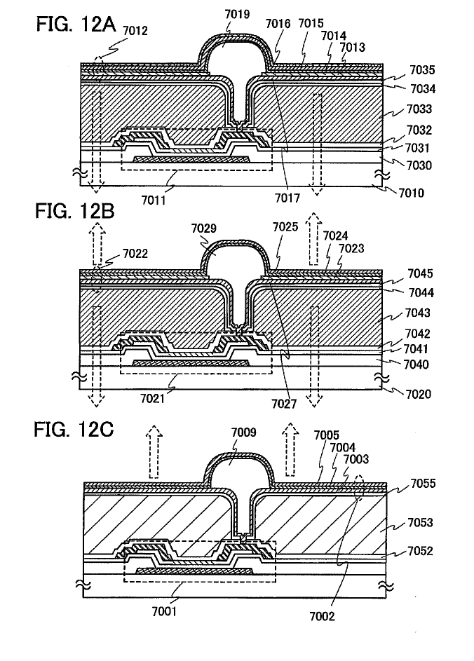

Next, a light-emitting element having a bottom emission structure is described with reference to FIG. 12A.

FIG. 12A is a cross-sectional view of a pixel of the case where a TFT 7011 for driving the light-emitting element is of an n-type and light is emitted from a light-emitting element 7012 to a first electrode 7013 side. In FIG. 12A, the first electrode 7013 of the light-emitting element 7012 is formed over a light-transmitting conductive film 7017 which is electrically connected to a drain electrode layer of the TFT 7011 for driving the light-emitting element, and an EL layer 7014 and a second electrode 7015 are stacked in the order presented, over the first electrode 7013.

As the light-transmitting conductive film 7017, a light-transmitting conductive film such as a film of indium oxide including tungsten oxide, indium zinc oxide including tungsten oxide, indium oxide including titanium oxide, indium tin oxide including titanium oxide, indium tin oxide, indium zinc oxide, or indium tin oxide to which silicon oxide is added can be used.

Any of a variety of materials can be used for the first electrode 7013 of the light-emitting element. For example, in the case where the first electrode 7013 is used as a cathode, the first electrode 7013 is preferably formed using, for example, a material having a low work function such as an alkali metal such as Li or Cs; an alkaline earth metal such as Mg, Ca, or Sr; an alloy containing any of these metals (e.g., Mg:Ag or Al:Li); or a rare earth metal such as Yb or Er. In FIG. 12A, the first electrode 7013 is approximately formed to a thickness such that light is transmitted (preferably, approximately 5 nm to 30 nm). For example, an aluminum film having a thickness of 20 nm is used for the first electrode 7013.

Note that the light-transmitting conductive film 7017 and the first electrode 7013 may be formed by stacking a light-transmitting conductive film and an aluminum film and then performing selective etching. In this case, the etching can be performed using the same mask, which is preferable.

Further, the periphery of the first electrode 7013 is covered with a partition wall 7019. The partition wall 7019 is formed using an organic resin film of polyimide, acrylic, polyamide, epoxy, or the like; an inorganic insulating film; or organic polysiloxane. It is particularly preferable that the partition wall 7019 be formed using a photosensitive resin material to have an opening over the first electrode 7013 so that a sidewall of the opening is formed to have an inclined surface with continuous curvature. In the case where a photosensitive resin material is used for the partition wall 7019, a step of forming a resist mask can be omitted.

As the EL layer 7014 formed over the first electrode 7013 and the partition wall 7019, an EL layer including at least a light-emitting layer is acceptable. Further, the EL layer 7014 may be formed to have either a single-layer structure or a stacked-layer structure. When the EL layer 7014 is formed using a plurality of layers, an electron-injection layer, an electron-transport layer, a light-emitting layer, a hole-transport layer, and a hole-injection layer are stacked in the order presented over the first electrode 7013 functioning as a cathode. Note that it is not necessary to form all of these layers.

The stacking order is not limited to the above order. The first electrode 7013 may serve as an anode, and a hole-injection layer, a hole-transport layer, a light-emitting layer, an electron-transport layer, and an electron-injection layer may be stacked in the order presented over the first electrode 7013. However, considering power consumption, it is preferable that the first electrode 7013 serve as a cathode and an electron-injection layer, an electron-transport layer, a light-emitting layer, a hole-transport layer, and a hole-injection layer be stacked in the order presented over the first electrode 7013 because an increase in voltage of a driver circuit portion can be prevented and power consumption can be reduced more effectively than in the case of using the first electrode 7013 as the anode and the layers stacked in the above order.

Further, any of a variety of materials can be used for the second electrode 7015 formed over the EL layer 7014. For example, in the case where the second electrode 7015 is used as an anode, a material having a high work function, for example, ZrN, Ti, W, Ni, Pt, Cr, or the like; or a transparent conductive material such as ITO, IZO, or ZnO is preferable. Further, a shielding film 7016, for example, a metal which blocks light, a metal which reflects light, or the like is provided over the second electrode 7015. In this embodiment, an ITO film is used as the second electrode 7015, and a Ti film is used as the shielding film 7016.

The light-emitting element 7012 corresponds to a region where the EL layer 7014 including the light-emitting layer is sandwiched between the first electrode 7013 and the second electrode 7015. In the case of the element structure illustrated in FIG. 12A, light emitted from the light-emitting element 7012 is ejected to the first electrode 7013 side as indicated by an arrow.

Note that in FIG. 12A, light emitted from the light-emitting element 7012 is ejected through a color filter layer 7033 and through a gate insulating layer 7031, an insulating layer 7030, and a substrate 7010.

The color filter layer 7033 is formed by a droplet discharge method such as an inkjet method, a printing method, an etching method with the use of a photolithography technique, or the like.

The color filter layer 7033 is covered with an overcoat layer 7034, and also covered with a protective insulating layer 7035. Note that although the overcoat layer 7034 with a small thickness is illustrated in FIG. 12A, the overcoat layer 7034 is formed using a resin material such as an acrylic resin and has a function of planarizing a surface with unevenness due to the color filter layer 7033.

A contact hole which is formed in the protective insulating layer 7035 and the insulating layer 7032 and reaches the drain electrode layer is provided in a portion which overlaps with the partition wall 7019.

A light-emitting element having a dual emission structure is described with reference to FIG. 12B.

In FIG. 12B, a first electrode 7023 of a light-emitting element 7022 is formed over a light-transmitting conductive film 7027 which is electrically connected to a drain electrode layer of the TFT 7021 for driving the light-emitting element, and an EL layer 7024 and a second electrode 7025 are stacked in the order presented over the first electrode 7023.

As the light-transmitting conductive film 7027, a light-transmitting conductive film such as a film of indium oxide including tungsten oxide, indium zinc oxide including tungsten oxide, indium oxide including titanium oxide, indium tin oxide including titanium oxide, indium tin oxide, indium zinc oxide, or indium tin oxide to which silicon oxide is added can be used.

Any of a variety of materials can be used for the first electrode 7023. For example, in the case where the first electrode 7023 is used as a cathode, the first electrode 7023 is preferably formed using, for example, a material having a low work function such as an alkali metal such as Li or Cs; an alkaline earth metal such as Mg, Ca, or Sr; an alloy containing any of these metals (e.g., Mg:Ag or Al:Li); or a rare earth metal such as Yb or Er. In this embodiment, the first electrode 7023 is used as a cathode, and the first electrode 7023 is approximately formed to a thickness such that light is transmitted (preferably, approximately 5 nm to 30 nm). For example, an aluminum film having a thickness of 20 nm is used as the cathode.

Note that the light-transmitting conductive film 7027 and the first electrode 7023 may be formed by stacking the light-transmitting conductive film and the aluminum film and then performing selective etching. In this case, the etching can be performed using the same mask, which is preferable.

Further, the periphery of the first electrode 7023 is covered with a partition wall 7029. The partition wall 7029 is formed using an organic resin film of polyimide, acrylic, polyamide, epoxy, or the like; an inorganic insulating film; or organic polysiloxane. It is particularly preferable that the partition wall 7029 be formed using a photosensitive resin material to have an opening over the first electrode 7023 so that a sidewall of the opening is formed to have an inclined surface with continuous curvature. In the case where a photosensitive resin material is used for the partition wall 7029, a step of forming a resist mask can be omitted.

As the EL layer 7024 formed over the first electrode 7023 and the partition wall 7029, an EL layer including a light-emitting layer is acceptable. Further, the EL layer 7024 may be formed to have either a single-layer structure or a stacked-layer structure. When the EL layer 7024 is formed using a plurality of layers, an electron-injection layer, an electron-transport layer, a light-emitting layer, a hole-transport layer, and a hole-injection layer are stacked in the order presented over the first electrode 7023 functioning as a cathode. Note that it is not necessary to form all of these layers.

The stacking order is not limited to the above order. The first electrode 7023 may serve as an anode and a hole-injection layer, a hole-transport layer, a light-emitting layer, an electron-transport layer, and an electron-injection layer may be stacked in the order presented over the first electrode 7023. However, considering power consumption, it is preferable that the first electrode 7023 is used as a cathode and an electron-injection layer, an electron-transport layer, a light-emitting layer, a hole-transport layer, and a hole-injection layer be stacked in the order presented over the cathode because power consumption can be reduced more effectively than in the case of using the first electrode 7023 as the anode and the layers stacked in the above order.

Further, any of a variety of materials can be used for the second electrode 7025 formed over the EL layer 7024. For example, in the case where the second electrode 7025 is used as an anode, a material having a high work function, for example, a transparent conductive material such as ITO, IZO, or ZnO is preferable. In this embodiment, the second electrode 7025 is formed using an ITO film including silicon oxide and is used as an anode.

The light-emitting element 7022 corresponds to a region where the EL layer 7024 including the light-emitting layer is sandwiched between the first electrode 7023 and the second electrode 7025. In the case of the element structure illustrated in FIG. 12B, light emitted from the light-emitting element 7022 is ejected to both the second electrode 7025 side and the first electrode 7023 side as indicated by arrows.

Note that in FIG. 12B, light emitted from the light-emitting element 7022 to the first electrode 7023 side is ejected through a color filter layer 7043 and through a gate insulating layer 7041, an insulating layer 7040, and a substrate 7020.

The color filter layer 7043 is formed by a droplet discharge method such as an inkjet method, a printing method, an etching method with the use of a photolithography technique, or the like.

The color filter layer 7043 is covered with an overcoat layer 7044, and also covered with a protective insulating layer 7045.

A contact hole which is formed in the protective insulating layer 7045 and the insulating layer 7042 and reaches the drain electrode layer is provided in a portion which overlaps with the partition wall 7029.

Note that in the case where the light-emitting element having a dual emission structure is used and full color display is performed on both display surfaces, light from the second electrode 7025 side does not pass through the color filter layer 7043; therefore, a sealing substrate provided with another color filter layer is preferably provided on the second electrode 7025.

Next, a light-emitting element having a top emission structure is described with reference to FIG. 12C.

FIG. 12C is a cross-sectional view of a pixel of the case where a TFT 7001 for driving the light-emitting element is of an n-type and light is emitted from a light-emitting element 7002 to pass through a second electrode 7005. In FIG. 12C, a first electrode 7003 of the light-emitting element 7002, which is electrically connected to a drain electrode layer of the TFT 7001 for driving the light-emitting element is formed, and an EL layer 7004 and the second electrode 7005 are stacked in the order presented over the first electrode 7003.

Any of a variety of materials can be used for the first electrode 7003. For example, in the case where the first electrode 7003 is used as a cathode, the first electrode 7003 is preferably formed using a material having a low work function such as an alkali metal such as Li or Cs; an alkaline earth metal such as Mg, Ca, or Sr; an alloy containing any of these metals (e.g., Mg:Ag or Al:Li); or a rare earth metal such as Yb or Er.

Further, the periphery of the first electrode 7003 is covered with a partition wall 7009. The partition wall 7009 is formed using an organic resin film of polyimide, acrylic, polyamide, epoxy, or the like; an inorganic insulating film; or organic polysiloxane. It is particularly preferable that the partition wall 7009 be formed using a photosensitive resin material to have an opening over the first electrode 7003 so that a sidewall of the opening is formed to have an inclined surface with continuous curvature. In the case where a photosensitive resin material is used for the partition wall 7009, a step of forming a resist mask can be omitted.

As the EL layer 7004 formed over the first electrode 7003 and the partition wall 7009, an EL layer including at least a light-emitting element is acceptable. Further, the EL layer 7004 may be formed to have either a single-layer structure or a stacked-layer structure. When the EL layer 7004 is formed using a plurality of layers, an electron-injection layer, an electron-transport layer, a light-emitting layer, a hole-transport layer, and a hole-injection layer are stacked in the order presented over the first electrode 7003 used as a cathode. Note that it is not necessary to form all of these layers.

The stacking order is not limited to the above order, and a hole-injection layer, a hole-transport layer, a light-emitting layer, an electron-transport layer, and an electron-injection layer may be stacked in the order presented over the first electrode 7003 used as an anode.

In FIG. 12C, a hole-injection layer, a hole-transport layer, a light-emitting layer, an electron-transport layer, and an electron-injection layer are stacked in the order presented over a stacked-layer film in which a Ti film, an aluminum film, and a Ti film are stacked in the order presented, and thereover, a stacked layer of a Mg:Ag alloy thin film and ITO is formed.

However, in the case where the TFT 7001 for driving the light-emitting element is of an n-type, it is preferable that an electron-injection layer, an electron-transport layer, a light-emitting layer, a hole-transport layer, and a hole-injection layer be stacked in the order presented over the first electrode 7003 because an increase in voltage of a driver circuit can be prevented and power consumption can be reduced more effectively than in the case of using the layers stacked in the above order.

The second electrode 7005 is formed using a light-transmitting conductive film such as a film of indium oxide including tungsten oxide, indium zinc oxide including tungsten oxide, indium oxide including titanium oxide, indium tin oxide including titanium oxide, indium tin oxide, indium zinc oxide, or indium tin oxide to which silicon oxide is added.

The light-emitting element 7002 corresponds to a region where the EL layer 7004 including the light-emitting layer is sandwiched between the first electrode 7003 and the second electrode 7005. In the case of the pixel illustrated in FIG. 12C, light emitted from the light-emitting element 7002 is ejected to the second electrode 7005 side as indicated by an arrow.

In FIG. 12C, an example in which the thin film transistor 410 is used as the TFT 7001 for driving the light-emitting element is illustrated; however, there is no particular limitation, and the thin film transistor 420 can be alternatively used.

In FIG. 12C, the drain electrode layer of the TFT 7001 for driving the light-emitting element is electrically connected to the first electrode 7003 through a contact hole provided in a protective insulating layer 7052 and an insulating layer 7055. A planarization insulating layer 7053 can be formed using a resin material such as polyimide, acrylic, benzocyclobutene, polyamide, or epoxy. Other than such resin materials, it is also possible to use a low-dielectric constant material (low-k material), a siloxane-based resin, phosphosilicate glass (PSG), borophosphosilicate glass (BPSG), or the like. Note that the planarization insulating layer 7053 may be formed by stacking a plurality of insulating films formed using these materials. There is no particular limitation on the method for forming the planarization insulating layer 7053, and the planarization insulating layer 7053 can be formed, depending on the material, by a method such as a sputtering method, an SOG method, spin coating, dipping, spray coating, or a droplet discharge method (e.g., an inkjet method, screen printing, or offset printing), or with a tool (equipment) such as a doctor knife, a roll coater, a curtain coater, or a knife coater.

The partition wall 7009 is provided in order to insulate the first electrode 7003 from a first electrode of an adjacent pixel. The partition wall 7009 is formed using an organic resin film of polyimide, acrylic, polyamide, epoxy, or the like; an inorganic insulating film; or organic polysiloxane. It is particularly preferable that the partition wall 7009 be formed using a photosensitive resin material to have an opening over the first electrode 7003 so that a sidewall of the opening is formed as an inclined surface with continuous curvature. In the case where a photosensitive resin material is used for the partition wall 7009, a step of forming a resist mask can be omitted.

In the structure illustrated in FIG. 12C, for performing full-color display, the light-emitting element 7002, one of adjacent light-emitting elements, and the other of the adjacent light-emitting elements are, for example, a green emissive light-emitting element, a red emissive light-emitting element, and a blue emissive light-emitting element, respectively. Alternatively, a light-emitting display device capable of full color display may be manufactured using four kinds of light-emitting elements which include a white light-emitting element in addition to three kinds of light-emitting elements.

In the structure of FIG. 12C, a light-emitting display device capable of full color display may be manufactured in such a way that all of a plurality of light-emitting elements which is arranged is white light-emitting elements and a sealing substrate having a color filter or the like is arranged on the light-emitting element 7002. A material which exhibits a single color such as white is formed and combined with a color filter or a color conversion layer, whereby full color display can be performed.

Needless to say, display of monochromatic light can also be performed. For example, a lighting system may be formed with the use of white light emission, or an area-color light-emitting device may be formed with the use of a single color light emission.

If necessary, an optical film such as a polarizing film including a circularly polarizing plate may be provided.

Note that, although the organic EL elements are described here as the light-emitting elements, an inorganic EL element can also be provided as a light-emitting element

The example is described in which a thin film transistor (a TFT for driving a light-emitting element) which controls the driving of a light-emitting element is electrically connected to the light-emitting element; however, a structure may be employed in which a TFT for current control is connected between the TFT for driving the light-emitting element and the light-emitting element.

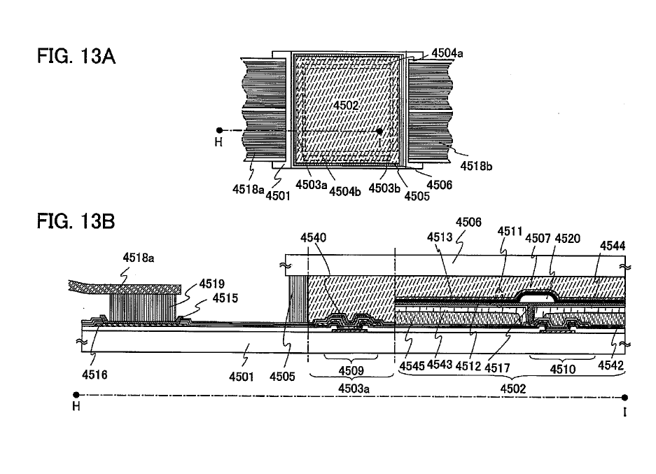

FIGS. 13A and 13B illustrate an appearance and a cross section of a light-emitting display panel (also referred to as a light-emitting panel).

FIG. 13A is a plan view of a panel in which a thin film transistor and a light-emitting element that are formed over a first substrate are sealed between the first substrate and a second substrate with a sealant. FIG. 13B is a cross-sectional view taken along H-I in FIG. 13A.

A sealant 4505 is provided to surround a pixel portion 4502, signal line driver circuits 4503a and 4503b, and scan line driver circuits 4504a and 4504b which are provided over a first substrate 4501. In addition, a second substrate 4506 is provided over the pixel portion 4502, the signal line driver circuits 4503a and 4503b, and the scan line driver circuits 4504a and 4504b. Accordingly, the pixel portion 4502, the signal line driver circuits 4503a and 4503b, and the scan line driver circuits 4504a and 4504b are sealed together with a filler 4507, by the first substrate 4501, the sealant 4505, and the second substrate 4506. It is preferable that a panel be packaged (sealed) with a protective film (such as a laminate film or an ultraviolet curable resin film) or a cover material with high air-tightness and little degasification so that the panel is not exposed to the outside air, in this manner

The pixel portion 4502, the signal line driver circuits 4503a and 4503b, and the scan line driver circuits 4504a and 4504b, which are formed over the first substrate 4501, each include a plurality of thin film transistors. A thin film transistor 4510 included in the pixel portion 4502 and a thin film transistor 4509 included in the signal line driver circuit 4503a are illustrated as an example in FIG. 13B.

The thin film transistor 410 whose parasitic capacitance is reduced, which is described in Embodiment 1, can be used for the thin film transistor 4510 for a pixel. The thin film transistor described in Embodiment 1 can also be used for the thin film transistor 4509 for a driver circuit. A conductive layer 4540 is provided over a portion overlapping with the channel formation region of the oxide semiconductor layer in the thin film transistor 4509 for the driver circuit. In this embodiment, the thin film transistors 4509 and 4510 are n-channel thin film transistors.

The conductive layer 4540 is provided over part of an oxide insulating layer 4542, which overlaps with the channel formation region of the oxide semiconductor layer in the thin film transistor 4509 for the driver circuit. The conductive layer 4540 is provided at the position overlapping with the channel formation region of the oxide semiconductor layer, whereby the amount of change in threshold voltage of the thin film transistor 4509 before and after the BT test can be reduced. A potential of the conductive layer 4540 may be the same or different from that of a gate electrode layer in the thin film transistor 4509. The conductive layer 4540 can also function as a second gate electrode layer. Alternatively, the potential of the conductive layer 4540 may be GND or 0 V, or the conductive layer 4540 may be in a floating state.

Further, the thin film transistor 4510 is electrically connected to a first electrode 4517. Further, the oxide insulating layer 4542 covering the oxide semiconductor layer of the thin film transistor 4510 is formed.

The oxide insulating layer 4542 can be formed using a material and a method which are similar to those of the oxide insulating layer 416 described in Embodiment 1. Further, as the insulating layer 4544, a silicon oxide film may be formed by a sputtering method in a manner similar to a protective insulating layer 403.

A color filter layer 4545 is formed over the thin film transistor 4510 to overlap with a light-emitting region of a light-emitting element 4511.

Further, in order to reduce the surface roughness due to the color filter layer 4545, the color filter layer 4545 is covered with an overcoat layer 4543 functioning as a planarization insulating film.

Further, the insulating layer 4544 is formed over the overcoat layer 4543.

Reference numeral 4511 denotes a light-emitting element. The first electrode 4517 which is a pixel electrode included in the light-emitting element 4511 is electrically connected to a source electrode layer or a drain electrode layer of the thin film transistor 4510. Note that the light-emitting element 4511 has a stacked-layer structure of the first electrode 4517, an electroluminescent layer 4512, and a second electrode 4513, and there is no particular limitation on the structure. The structure of the light-emitting element 4511 can be changed as appropriate depending on the direction in which light is extracted from the light-emitting element 4511, or the like.

A partition wall 4520 is formed using an organic resin film, an inorganic insulating film, or organic polysiloxane. It is particularly preferable that the partition wall 4520 be formed using a photosensitive material to have an opening portion over the first electrode 4517 so that a sidewall of the opening portion is formed as a tilted surface with continuous curvature.

The electroluminescent layer 4512 may be formed to have either a single-layer structure or a stacked-layer structure.

In order to prevent entry of oxygen, hydrogen, moisture, carbon dioxide, or the like into the light-emitting element 4511, a protective film may be formed over the second electrode 4513 and the partition wall 4520. As the protective film, a silicon nitride film, a silicon nitride oxide film, a DLC film, or the like can be formed.

In addition, a variety of signals and potentials are supplied to the signal line driver circuits 4503a and 4503b, the scan line driver circuits 4504a and 4504b, or the pixel portion 4502 from FPCs 4518a and 4518b.

A connection terminal electrode 4515 is formed using the same conductive film as the first electrode 4517 included in the light-emitting element 4511, and a terminal electrode 4516 is formed using the same conductive film as the source and drain electrode layers included in the thin film transistor 4509.

The connection terminal electrode 4515 is electrically connected to a terminal included in the FPC 4518a through an anisotropic conductive film 4519.

The second substrate located in the direction in which light is extracted from the light-emitting element 4511 should have a light-transmitting property. In that case, a light-transmitting material such as a glass plate, a plastic plate, a polyester film, or an acrylic film is used for the second substrate 4506.

As the filler 4507, an ultraviolet curable resin or a thermosetting resin can be used, as well as an inert gas such as nitrogen or argon. For example, PVC (polyvinyl chloride), acrylic, polyimide, an epoxy resin, a silicone resin, PVB (polyvinyl butyral), or EVA (ethylene vinyl acetate) can be used. For example, nitrogen is used for the filler.

In addition, if needed, an optical film, such as a polarizing plate, a circularly polarizing plate (including an elliptically polarizing plate), a retardation plate (a quarter-wave plate or a half-wave plate), or a color filter, may be provided as appropriate on a light-emitting surface of the light-emitting element. Further, the polarizing plate or the circularly polarizing plate may be provided with an anti-reflection film. For example, anti-glare treatment by which reflected light can be diffused by projections and depressions on the surface to reduce the glare can be performed.

As the signal line driver circuits 4503a and 4503b and the scan line driver circuits 4504a and 4504b, driver circuits formed using a single crystal semiconductor film or a polycrystalline semiconductor film over a substrate separately prepared may be used and mounted. Alternatively, only the signal line driver circuits or a part thereof, or only the scan line driver circuits or a part thereof may be separately formed and mounted. This embodiment is not limited to the structure illustrated in FIGS. 13A and 13B.

According to the foregoing steps, a light-emitting display device (display panel) which realizes low power consumption can be manufactured.

This embodiment can be freely combined with any of Embodiments 1 to 3.

### Embodiment 8

In this embodiment, an example will be described below in which at least part of a driver circuit and a thin film transistor to be disposed in a pixel portion are formed over one substrate.

The thin film transistor to be disposed in the pixel portion is formed according to Embodiment 1 or Embodiment 3. The thin film transistor described in Embodiment 1 or Embodiment 3 is an n-channel TFT; therefore, part of a driver circuit which can be formed using an n-channel TFT is formed over the same substrate as the thin film transistor of the pixel portion.

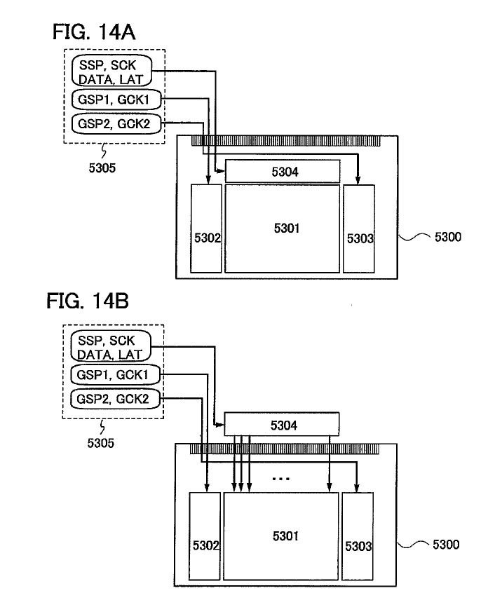

FIG. 14A illustrates an example of a block diagram of an active matrix display device. Over a substrate 5300 in the display device, a pixel portion 5301, a first scan line driver circuit 5302, a second scan line driver circuit 5303, and a signal line driver circuit 5304 are provided. In the pixel portion 5301, a plurality of signal lines which is extended from the signal line driver circuit 5304 is provided and a plurality of scan lines which is extended from the first scan line driver circuit 5302 and the second scan line driver circuit 5303 is provided. Note that pixels which include display elements are provided in a matrix in respective regions where the scan lines and the signal lines intersect with each other. Further, the substrate 5300 in the display device is connected to a timing control circuit 5305 (also referred to as a controller or a controller IC) through a connection portion such as a flexible printed circuit (FPC).

In FIG. 14A, the first scan line driver circuit 5302, the second scan line driver circuit 5303, and the signal line driver circuit 5304 are formed over the substrate 5300 where the pixel portion 5301 is formed. Accordingly, the number of components of a driver circuit which is provided outside and the like are reduced, so that reduction in cost can be achieved. Moreover, the number of connections in the connection portion in the case where wirings are extended from a driver circuit provided outside the substrate 5300 can be reduced, and the reliability or yield can be increased.

Note that as an example, the timing control circuit 5305 supplies a first scan line driver circuit start signal (GSP1) and a scan line driver circuit clock signal (GCK1) to the first scan line driver circuit 5302. The timing control circuit 5305 supplies, for example, a second scan line driver circuit start signal (GSP2) (also referred to as a start pulse) and a scan line driver circuit clock signal (GCK2) to the second scan line driver circuit 5303. The timing control circuit 5305 supplies a signal line driver circuit start signal (SSP), a signal line driver circuit clock signal (SCK), video signal data (DATA) (also simply referred to as a video signal) and a latch signal (LAT) to the signal line driver circuit 5304. Note that each clock signal may be a plurality of clock signals whose periods are different or may be supplied together with an inverted clock signal (CKB). Note that one of the first scan line driver circuit 5302 and the second scan line driver circuit 5303 can be omitted.

FIG. 14B illustrates a structure in which circuits with lower driving frequency (e.g., the first scan line driver circuit 5302 and the second scan line driver circuit 5303) are formed over the substrate 5300 where the pixel portion 5301 is formed, and the signal line driver circuit 5304 is formed over a substrate which is different from the substrate 5300 where the pixel portion 5301 is formed. With this structure, a driver circuit formed over the substrate 5300 can be constituted by using thin film transistors with lower field-effect mobility as compared to that of a transistor formed using a single crystal semiconductor. Accordingly, increase in the size of the display device, reduction in the number of steps, reduction in cost, improvement in yield, or the like can be achieved.

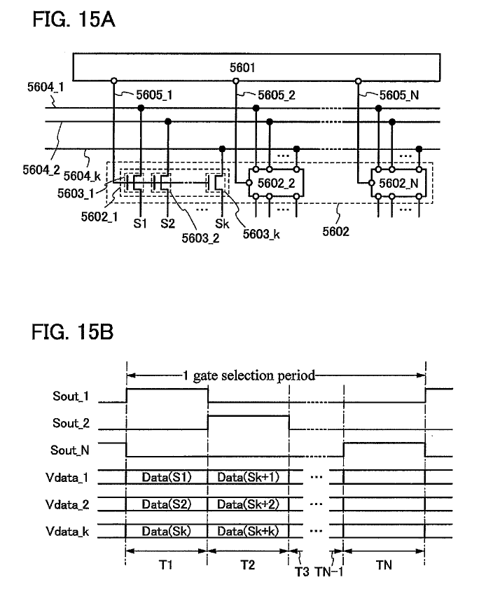

The thin film transistor described in Embodiment 1 or Embodiment 3 is an n-channel TFT. FIGS. 15A and 15B illustrate an example of a structure and operation of a signal line driver circuit constituted by n-channel TFTs.

The signal line driver circuit includes a shift register 5601 and a switching circuit 5602. The switching circuit 5602 includes a plurality of switching circuits 5602_1 to 5602_N (N is a natural number). The switching circuits 5602_1 to 5602_N each include a plurality of thin film transistors 5603_1 to 5603_{—}k (k is a natural number). An example in which the thin film transistors 5603_1 to 5603_{—}k are n-channel TFTs will be described.

A connection relation of the signal line driver circuit will be described by using the switching circuit 5602_1 as an example. First terminals of the thin film transistors 5603_1 to 5603_{—}k are connected to wirings 5604_1 to 5604_{—}k, respectively. Second terminals of the thin film transistors 5603_1 to 5603_{—}k are connected to signal lines S1 to Sk, respectively. Gates of the thin film transistors 5603_1 to 5603_{—}k are connected to a wiring 5605_1.

The shift register 5601 has a function of outputting an H level signal (also referred to as an H signal or a high power supply potential level) to the wirings 5605_1 to 5605_N in order and selecting the switching circuits 5602_1 to 5602_N in order.

The switching circuit 5602_1 has a function of controlling conduction states between the wirings 5604_1 to 5604_{—}k and the signal lines S1 to Sk (conduction between the first terminal and the second terminal), that is, a function of controlling whether the potentials of the wirings 5604_1 to 5604_{—}k are supplied or not to the signal lines S1 to Sk As thus described, the switching circuit 5602_1 has a function as a selector. Further, the thin film transistors 5603_1 to 5603_{—}k each have a function of controlling electrical continuity between the wirings 5604_1 to 5604_{—}k and the signal lines S1 to Sk, namely a function of controlling whether or not to supply the potentials of the wirings 5604_1 to 5604_{—}k to the signal lines S1 to Sk. In this manner, each of the thin film transistors 5603_1 to 5603_{—}k has a function as a switch.

Note that video signal data (DATA) is input to each of the wirings 5604_1 to 5604_{—}k. The video signal data (DATA) is an analog signal corresponding to image data or image signals in many cases.

Next, the operation of the signal line driver circuit in FIG. 15A is described with reference to a timing chart in FIG. 15B. FIG. 15B illustrates examples of signals Sout_1 to Sout_N and signals Vdata_1 to Vdata_k. The signals Sout_1 to Sout_N are examples of output signals of the shift register 5601, and the signals Vdata_1 to Vdata_k are examples of signals which are input to the wirings 5604_1 to 5604_{—}k. Note that one operation period of the signal line driver circuit corresponds to one gate selection period in a display device. For example, one gate selection period is divided into periods T1 to TN. The periods T1 to TN are periods for writing video signal data (DATA) to the pixels which belong to a selected row.

Note that signal waveform distortion and the like in each structure illustrated in drawings and the like in this embodiment are exaggerated for simplicity in some cases. Therefore, this embodiment is not necessarily limited to the scale illustrated in the drawing and the like.

In the periods T1 to TN, the shift register 5601 sequentially outputs H level signals to the wirings 5605_1 to 5605_N. For example, in the period T1, the shift register 5601 outputs an H level signal to the wiring 5605_1. Then, the thin film transistors 5603_1 to 5603_{—}k are turned on, so that the wirings 5604_1 to 5604_{—}k and the signal lines S1 to Sk have electrical continuity. In this case, Data (S1) to Data (Sk) are input to the wirings 5604_1 to 5604_{—}k, respectively. The Data (S1) to Data (Sk) are input to pixels in a selected row in a first to k-th columns through the thin film transistors 5603_1 to 5603_{—}k, respectively. Thus, in the periods T1 to TN, video signal data (DATA) is sequentially written to the pixels in the selected row of every k columns.

By writing video signal data (DATA) to pixels of every plurality of columns, the number of video signal data (DATA) or the number of wirings can be reduced. Thus, connections to an external circuit can be reduced. By writing video signals to pixels of every plurality of columns, writing time can be extended and insufficient of writing of video signals can be prevented.

Note that a circuit including the thin film transistor described in Embodiment 1 or Embodiment 3 can be used as the shift register 5601 and the switching circuit 5602. In that case, the shift register 5601 can be constituted by only n-channel transistors.

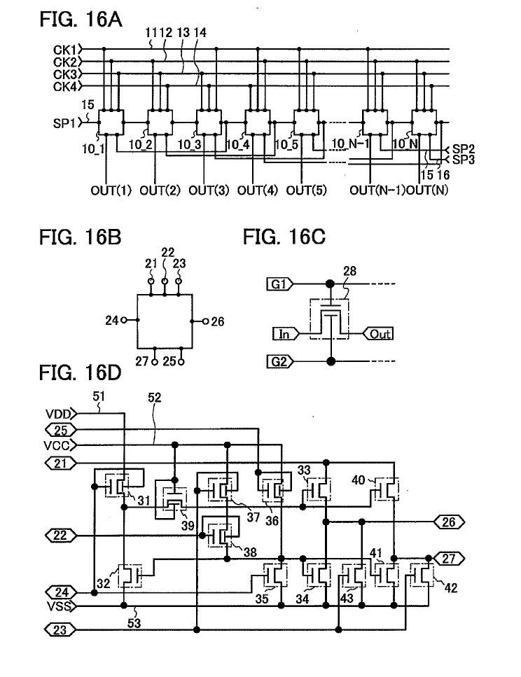

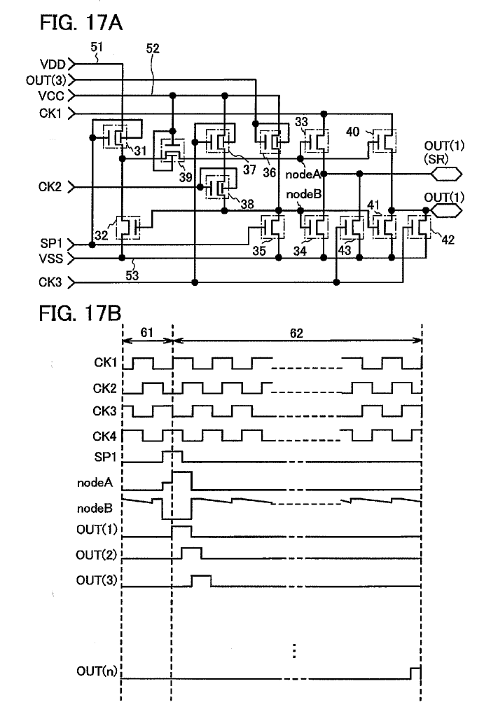

An embodiment of a shift register which is used for part of the scan line driver circuit and/or the signal line driver circuit is described with reference to FIGS. 16A to 16D and FIGS. 17A and 17B.

The scan line driver circuit includes a shift register. Additionally, the scan line driver circuit may include a level shifter, a buffer, and the like in some cases. In the scan line driver circuit, when the clock signal (CLK) and the start pulse signal (SP) are input to the shift register, a selection signal is generated. The generated selection signal is buffered and amplified by the buffer, and the resulting signal is supplied to a corresponding scan line. Gate electrodes of transistors in pixels of one line are connected to the scan line. Since the transistors in the pixels of one line have to be turned on all at once, a buffer which can supply a large current is used.

The shift register in the scan line driver circuit and/or the signal line driver circuit is described with reference to FIGS. 16A to 16D and FIGS. 17A and 17B. The shift register includes a first to Nth pulse output circuits 10_1 to 10_N (N is a natural number greater than or equal to 3) (see FIG. 16A). In the shift register illustrated in FIG. 16A, a first clock signal CK1, a second clock signal CK2, a third clock signal CK3, and a fourth clock signal CK4 are supplied from a first wiring 11, a second wiring 12, a third wiring 13, and a fourth wiring 14, respectively, to the first to Nth pulse output circuits 10_1 to 10_N. A start pulse SP1 (a first start pulse) from a fifth wiring 15 is input to the first pulse output circuit 10_1. To the n-th pulse output circuit 10_{—}n of the second or subsequent stage (n is a natural number greater than or equal to 2 and less than or equal to N), a signal from the pulse output circuit of the preceding stage (such a signal is referred to as a preceding-stage signal OUT(n−1)) (n is a natural number greater than or equal to 2 and less than or equal to N) is input. To the first pulse output circuit 10_1, a signal from the third pulse output circuit 10_3 of the stage following the next stage is input. Similarly, to the nth pulse output circuit 10_{—}n of the second or subsequent stage, a signal from the (n+2)th pulse output circuit 10_(n+2) of the stage following the next stage (such a signal is referred to as a subsequent-stage signal OUT(n+2)) is input. Therefore, the pulse output circuits of the respective stages output first output signals (OUT(1)(SR) to OUT(N)(SR)) to be input to the pulse output circuit of the subsequent stage and/or the pulse output circuit of the stage before the preceding stage and second output signals (OUT(1) to OUT(N)) to be input to another circuit or the like. Note that since the subsequent-stage signal OUT(n+2) is not input to the last two stages of the shift register as illustrated in FIG. 16A, a second start pulse SP2 and a third start pulse SP3 may be additionally input to the pulse output circuits of the last two stages, for example.

Note that a clock signal (CK) is a signal which oscillates between an H level and an L level (referred to as an L signal or a low power supply potential level) at a constant cycle. The first to the fourth clock signals (CK1) to (CK4) are delayed by ¼ period sequentially. In this embodiment, by using the first to fourth clock signals (CK1) to (CK4), control or the like of driving of a pulse output circuit is performed. Note that, the clock signal is also referred to as GCK or SCK in some cases depending on a driver circuit to which the clock signal is input; the clock signal is referred to as CK in the following description.

A first input terminal 21, a second input terminal 22, and a third input terminal 23 are electrically connected to any of the first to fourth wirings 11 to 14. For example, in the first pulse output circuit 10_1 in FIG. 16A, the first input terminal 21 is electrically connected to the first wiring 11, the second input terminal 22 is electrically connected to the second wiring 12, and the third input terminal 23 is electrically connected to the third wiring 13. In the second pulse output circuit 10_2, the first input terminal 21 is electrically connected to the second wiring 12, the second input terminal 22 is electrically connected to the third wiring 13, and the third input terminal 23 is electrically connected to the fourth wiring 14.

Each of the first to Nth pulse output circuits 10_1 to 10_N includes the first input terminal 21, the second input terminal 22, the third input terminal 23, a fourth input terminal 24, a fifth input terminal 25, a first output terminal 26, and a second output terminal 27 (see FIG. 16B). In the first pulse output circuit 10_1, the first clock signal CK1 is input to the first input terminal 21; the second clock signal CK2 is input to the second input terminal 22; the third clock signal CK3 is input to the third input terminal 23; the start pulse is input to the fourth input terminal 24; the subsequent stage signal OUT (3) is input to the fifth input terminal 25; the first output signal OUT (1) (SR) is output from the first output terminal 26; and the second output signal OUT (1) is output from the second output terminal 27.

Note that in the first to N-th pulse output circuits 10_1 to 10_N, a four-terminal thin film transistor having a back gate can be used in addition to a three-terminal thin film transistor. FIG. 16C illustrates the symbol of the four-terminal thin film transistor 28. The symbol of the thin film transistor 28 illustrated in FIG. 16C represents the four-terminal thin film transistor and is used in the drawings and the like below. Note that in this specification, when a thin film transistor has two gate electrodes with a semiconductor layer therebetween, the gate electrode below the semiconductor layer is called a lower gate electrode and the gate electrode above the semiconductor layer is called an upper gate electrode (also referred to as a back gate). The thin film transistor 28 is an element which can control electric current between an IN terminal and an OUT terminal with a first control signal G1 which is input to the lower gate electrode and a second control signal G2 which is input to the upper gate electrode.

When an oxide semiconductor is used for a semiconductor layer including a channel formation region in a thin film transistor, the threshold voltage sometimes shifts in the positive or negative direction depending on a manufacturing process. For that reason, the thin film transistor in which an oxide semiconductor is used for a semiconductor layer including a channel formation region preferably has a structure with which the threshold voltage can be controlled. The threshold voltage of the thin film transistor 28 illustrated in FIG. 16C can be controlled to be a desired level by providing gate electrodes above and below a channel formation region of the thin film transistor 28 with a gate insulating film interposed between the upper gate electrode and the channel formation region and between the lower gate electrode and the channel formation region, and by controlling a potential of the upper gate electrode and/or a potential of the lower gate electrode.

Next, an example of a specific circuit configuration of the pulse output circuit will be described with reference to FIG. 16D.

The pulse output circuit 10_1 includes a first to thirteenth transistors 31 to 43 (see FIG. 16D). A signal or a power supply potential is supplied to the first to thirteenth transistors 31 to 43 from a power supply line 51 to which a first high power supply potential VDD is supplied, a power supply line 52 to which a second high power supply potential VCC is supplied, and a power supply line 53 to which a low power supply potential VSS is supplied, in addition to the first to fifth input terminals 21 to 25, the first output terminal 26, and the second output terminal 27, which are described above. The relation of the power supply potentials of the power supply lines in FIG. 16D is as follows: the first power supply potential VDD is higher than or equal to the second power supply potential VCC, and the second power supply potential VCC is higher than the third power supply potential VSS. Note that the first to fourth clock signals (CK1) to (CK4) each alternate between an H level and an L level at regular intervals; the clock signal at the H level is VDD and the clock signal at the L level is VSS. By making the potential VDD of the power supply line 51 higher than the potential VCC of the power supply line 52, a potential applied to a gate electrode of a transistor can be lowered, shift in threshold voltage of the transistor can be reduced, and deterioration of the transistor can be suppressed without an adverse effect on the operation of the transistor. Note that as in FIG. 16D, the thin film transistor 28 with four terminals which is illustrated in FIG. 16C is preferably used as the first transistor 31 and the sixth to ninth transistors 36 to 39 among the first to thirteenth transistors 31 to 43. The first transistor 31 and the sixth to ninth transistors 36 to 39 need to switch a potential of a node to which one electrode serving as a source or a drain is connected depending on a control signal of the gate electrode, and can reduce a malfunction of the pulse output circuit by quick response (sharp rising of on-current) to the control signal input to the gate electrode. By using the thin film transistor 28 with four terminals which is illustrated in FIG. 16C, the threshold voltage can be controlled, and a malfunction of the pulse output circuit can be further reduced. Note that although the first control signal G1 and the second control signal G2 are the same control signals in FIG. 16D, the first control signal G1 and the second control signal G2 may be different control signals.

In FIG. 16D, a first terminal of the first transistor 31 is electrically connected to the power supply line 51, a second terminal of the first transistor 31 is electrically connected to a first terminal of the ninth transistor 39, and gate electrodes (a lower gate electrode and an upper gate electrode) of the first transistor 31 are electrically connected to the fourth input terminal 24. A first terminal of the second transistor 32 is electrically connected to the power supply line 53, a second terminal of the second transistor 32 is electrically connected to the first terminal of the ninth transistor 39, and a gate electrode of the second transistor 32 is electrically connected to a gate electrode of the fourth transistor 34. A first terminal of the third transistor 33 is electrically connected to the first input terminal 21, and a second terminal of the third transistor 33 is electrically connected to the first output terminal 26. A first terminal of the fourth transistor 34 is electrically connected to the power supply line 53, and a second terminal of the fourth transistor 34 is electrically connected to the first output terminal 26. A first terminal of the fifth transistor 35 is electrically connected to the power supply line 53, a second terminal of the fifth transistor 35 is electrically connected to the gate electrode of the second transistor 32 and the gate electrode of the fourth transistor 34, and a gate electrode of the fifth transistor 35 is electrically connected to the fourth input terminal 24. A first terminal of the sixth transistor 36 is electrically connected to the power supply line 52, a second terminal of the sixth transistor 36 is electrically connected to the gate electrode of the second transistor 32 and the gate electrode of the fourth transistor 34, and gate electrodes (a lower gate electrode and an upper gate electrode) of the sixth transistor 36 are electrically connected to the fifth input terminal 25. A first terminal of the seventh transistor 37 is electrically connected to the power supply line 52, a second terminal of the seventh transistor 37 is electrically connected to a second terminal of the eighth transistor 38, and gate electrodes (a lower gate electrode and an upper gate electrode) of the seventh transistor 37 are electrically connected to the third input terminal 23. A first terminal of the eighth transistor 38 is electrically connected to the gate electrode of the second transistor 32 and the gate electrode of the fourth transistor 34, and gate electrodes (a lower gate electrode and an upper gate electrode) of the eighth transistor 38 are electrically connected to the second input terminal 22. The first terminal of the ninth transistor 39 is electrically connected to the second terminal of the first transistor 31 and the second terminal of the second transistor 32, a second terminal of the ninth transistor 39 is electrically connected to a gate electrode of the third transistor 33 and a gate electrode of the tenth transistor 40, and gate electrodes (a lower gate electrode and an upper gate electrode) of the ninth transistor 39 are electrically connected to the power supply line 52. A first terminal of the tenth transistor 40 is electrically connected to the first input terminal 21, a second terminal of the tenth transistor 40 is electrically connected to the second output terminal 27, and the gate electrode of the tenth transistor 40 is electrically connected to the second terminal of the ninth transistor 39. A first terminal of the eleventh transistor 41 is electrically connected to the power supply line 53, a second terminal of the eleventh transistor 41 is electrically connected to the second output terminal 27, and a gate electrode of the eleventh transistor 41 is electrically connected to the gate electrode of the second transistor 32 and the gate electrode of the fourth transistor 34. A first terminal of the twelfth transistor 42 is electrically connected to the power supply line 53, a second terminal of the twelfth transistor 42 is electrically connected to the second output terminal 27, and a gate electrode of the twelfth transistor 42 is electrically connected to the gate electrodes (the lower gate electrode and the upper gate electrode) of the seventh transistor 37. A first terminal of the thirteenth transistor 43 is electrically connected to the power supply line 53, a second terminal of the thirteenth transistor 43 is electrically connected to the first output terminal 26, and a gate electrode of the thirteenth transistor 43 is electrically connected to the gate electrodes (the lower gate electrode and the upper gate electrode) of the seventh transistor 37.

In FIG. 16D, a portion where the gate electrode of the third transistor 33, the gate electrode of the tenth transistor 40, and the second terminal of the ninth transistor 39 are connected is referred to as a node A. In addition, a connection point of the gate electrode of the second transistor 32, the gate electrode of the fourth transistor 34, the second terminal of the fifth transistor 35, the second terminal of the sixth transistor 36, the first terminal of the eighth transistor 38, and the gate electrode of the eleventh transistor 41 is referred to as a node B.

FIG. 17A illustrates signals that are input to or output from the first to fifth input terminals 21 to 25 and the first and second output terminals 26 and 27 in the case where the pulse output circuit illustrated in FIG. 16D is applied to the first pulse output circuit 10_1.

Specifically, the first clock signal CK1 is input to the first input terminal 21; the second clock signal CK2 is input to the second input terminal 22; the third clock signal CK3 is input to the third input terminal 23; the start pulse is input to the fourth input terminal 24; the subsequent-stage signal OUT(3) is input to the fifth input terminal 25; the first output signal OUT(1)(SR) is output from the first output terminal 26; and the second output signal OUT(1) is output from the second output terminal 27.

Note that a thin film transistor is an element having at least three terminals of a gate, a drain, and a source. The thin film transistor has a semiconductor including a channel formation region formed in a region overlapping with the gate. Current that flows between the drain and the source through the channel region can be controlled by controlling a potential of the gate. Here, since the source and the drain of the thin film transistor may interchange depending on the structure, the operating condition, and the like of the thin film transistor, it is difficult to define which is a source or a drain. Therefore, a region functioning as source and drain is not called the source or the drain in some cases. In such a case, for example, one of the source and the drain may be referred to as a first terminal and the other thereof may be referred to as a second terminal.

Note that in FIG. 16D and FIG. 17A, a capacitor for performing bootstrap operation by bringing the node A into a floating state may be additionally provided. Furthermore, a capacitor having one electrode electrically connected to the node B may be additionally provided in order to hold a potential of the node B.

FIG. 17B illustrates a timing chart of a shift register including a plurality of pulse output circuits illustrated in FIG. 17A. Note that when the shift register is included in a scan line driver circuit, a period 61 in FIG. 17B corresponds to a vertical retrace period and a period 62 corresponds to a gate selection period.

Note that the placement of the ninth transistor 39 in which the second power supply potential VCC is applied to the gate as illustrated in FIG. 17A has the following advantages before and after bootstrap operation.

Without the ninth transistor 39 in which the second potential VCC is applied to the gate electrode, if a potential of the node A is raised by bootstrap operation, a potential of the source which is the second terminal of the first transistor 31 rises to a value higher than the first power supply potential VDD. Then, the source of the first transistor 31 is switched to the first terminal side, that is, on the power supply line 51 side. Consequently, in the first transistor 31, a high bias voltage is applied and thus significant stress is applied between the gate and the source and between the gate and the drain, which might cause deterioration of the transistor. Therefore, with the ninth transistor 39 in which the second power supply potential VCC is applied to the gate electrode, an increase in potential of the second terminal of the first transistor 31 can be prevented while the potential of the node A is raised by bootstrap operation. In other words, the placement of the ninth transistor 39 can lower the value of a negative bias voltage applied between the gate and the source of the first transistor 31. Thus, the circuit configuration in this embodiment can reduce a negative bias voltage applied between the gate and the source of the first transistor 31, so that deterioration of the first transistor 31 due to stress can be suppressed.

Note that the ninth transistor 39 is provided so as to be connected between the second terminal of the first transistor 31 and the gate of the third transistor 33 through the first terminal and the second terminal thereof. Note that when the shift register including a plurality of pulse output circuits in this embodiment is included in a signal line driver circuit having a larger number of stages than a scan line driver circuit, the ninth transistor 39 may be omitted, which is advantageous in that the number of transistors is reduced.

Note that an oxide semiconductor is used for semiconductor layers of the first to thirteenth transistors 31 to 43; thus, the off-state current of the thin film transistors can be reduced, the on-state current and field effect mobility can be increased, and the degree of degradation of the transistors can be reduced. Compared with a transistor formed using an oxide semiconductor and a transistor formed using amorphous silicon, the degree of deterioration of the transistor due to the application of a high potential to the gate electrode is low. Therefore, even when the first power supply potential VDD is supplied to a power supply line to which the second power supply potential VCC is supplied, a similar operation can be performed, and the number of power supply lines which are provided in a circuit can be reduced, so that the circuit can be miniaturized.

Note that a similar function is obtained even when the connection relation is changed so that a clock signal that is supplied to the gate electrodes (the lower gate electrode and the upper gate electrode) of the seventh transistor 37 from the third input terminal 23 and a clock signal that is supplied to the gate electrodes (the lower gate electrode and the upper gate electrode) of the eighth transistor 38 from the second input terminal 22 are supplied from the second input terminal 22 and the third input terminal 23, respectively. In the shift register illustrated in FIG. 17A, a state of the seventh transistor 37 and the eighth transistor 38 is changed so that both the seventh transistor 37 and the eighth transistor 38 are on, then the seventh transistor 37 is off and the eighth transistor 38 is on, and then the seventh transistor 37 and the eighth transistor 38 are off; thus, the fall in potential of the node B due to fall in potentials of the second input terminal 22 and the third input terminal 23 is caused twice by fall in potential of the gate electrode of the seventh transistor 37 and fall in potential of the gate electrode of the eighth transistor 38. On the other hand, in the shift register illustrated in FIG. 17A, when a state of the seventh transistor 37 and the eighth transistor 38 is changed as in the period in FIG. 17B so that both the seventh transistor 37 and the eighth transistor 38 are on, then the seventh transistor 37 is on and the eighth transistor 38 is off, and then the seventh transistor 37 and the eighth transistor 38 are off, the number of fall in potential of the node B due to fall in potentials of the second input terminal 22 and the third input terminal 23 occurs only once, which is caused by fall in potential of the gate electrode of the eighth transistor 38. Therefore, the connection relation, that is, the clock signal CK3 is supplied from the third input terminal 123 to the gate electrodes (the lower electrode and the upper electrode) of the seventh transistor 137 and the clock signal CK2 is supplied from the second input terminal 122 to the gate electrodes (the lower gate electrode and the upper gate electrode) of the eighth transistor 138, is preferable. This is because fluctuation of the potential of the node B can be reduced and noise can be reduced.

In this way, in a period during which the potentials of the first output terminal 26 and the second output terminal 27 are held at the L level, the H level signal is regularly supplied to the node B; therefore, malfunction of a pulse output circuit can be suppressed.

This embodiment can be freely combined with any of other embodiments.

### Embodiment 9

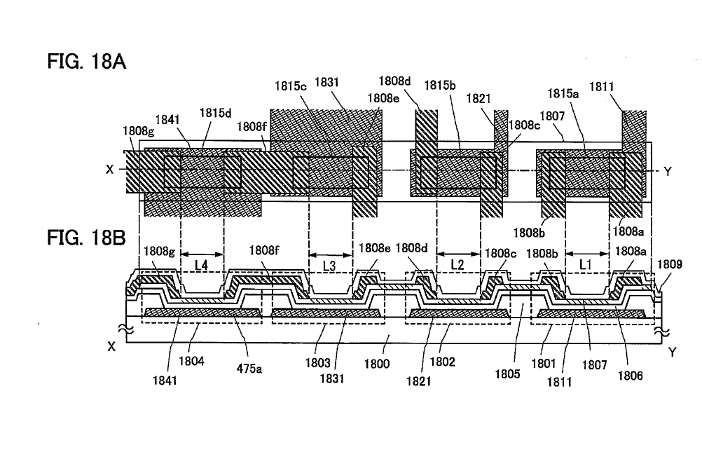

In this embodiment, an example in which a plurality of thin film transistors is provided using one oxide semiconductor layer is described with reference to FIGS. 18A and 18B. FIG. 18A is a top view of four thin film transistors.

FIG. 18B is a cross-sectional view of a first thin film transistor 1801, a second thin film transistor 1802, a third thin film transistor 1803, and a fourth thin film transistor 1804, which are provided over a substrate 1800. Note that FIG. 18B corresponds to a cross section taken along chain line X-Y in FIG. 18A.

The first thin film transistor 1801 includes an insulating layer 1805 having a tapered side surface, over a first gate electrode layer 1811; a gate insulating layer 1806 in contact with a top surface of the first gate electrode layer 1811; an oxide semiconductor layer 1807 over the gate insulating layer; electrode layers 1808a and 1808b serving as source and drain electrode layers, over the oxide semiconductor layer; and an oxide insulating layer 1809 in contact with the oxide semiconductor layer 1807. Note that a channel length L1 of the first thin film transistor 1801 is determined by the distance between the electrode layers 1808a and 1808b. Furthermore, a channel width of the first thin film transistor 1801 is determined by a width of an opening 1815a.

The second thin film transistor 1802 includes the insulating layer 1805 having a tapered side surface, over a second gate electrode layer 1821; the gate insulating layer 1806 in contact with a top surface of the second gate electrode layer 1821; the oxide semiconductor layer 1807 over the gate insulating layer; electrode layers 1808c and 1808d serving as source and drain electrode layers, over the oxide semiconductor layer; and the oxide insulating layer 1809 in contact with the oxide semiconductor layer 1807. Note that a channel length L2 of the second thin film transistor 1802 is determined by the distance between the electrode layers 1808c and 1808d. Furthermore, a channel width of the second thin film transistor 1802 is determined by a width of an opening 1815b.

The third thin film transistor 1803 includes the insulating layer 1805 having a tapered side surface, over a third gate electrode layer 1831; the gate insulating layer 1806 in contact with a top surface of the third gate electrode layer 1831; the oxide semiconductor layer 1807 over the gate insulating layer; electrode layers 1808e and 1808f serving as source and drain electrode layers, over the oxide semiconductor layer; and the oxide insulating layer 1809 in contact with the oxide semiconductor layer 1807. Note that a channel length L3 of the third thin film transistor 1803 is determined by the distance between the electrode layers 1808e and 1808f. Further, a channel width of the third thin film transistor 1803 is determined by a width of an opening 1815c.

The fourth thin film transistor 1804 includes the insulating layer 1805 having a tapered side surface, over a fourth gate electrode layer 1841; the gate insulating layer 1806 in contact with a top surface of the fourth gate electrode layer 1841; the oxide semiconductor layer 1807 over the gate insulating layer; the electrode layer 1808f and an electrode layer 1808g serving as source and drain electrode layers, over the oxide semiconductor layer; and the oxide insulating layer 1809 in contact with the oxide semiconductor layer 1807. Note that the electrode layer 1808f is shared by the third thin film transistor 1803 and the fourth thin film transistor 1804. Further, a channel length L4 of the fourth thin film transistor 1804 is determined by the distance between the electrode layers 1808f and 1808g. Furthermore, a channel width of the fourth thin film transistor 1804 is determined by a width of an opening 1815d.

As described above, the oxide semiconductor layer 1807 which is one island serves as a semiconductor layer of the four thin film transistors.

The openings in the insulating layer 1805 are illustrated in FIG. 18A. The opening (first opening) 1815a is provided such that the bottom of the opening is in contact with the top surface of the first gate electrode layer 1811. The opening (second opening) 1815b is provided such that the bottom of the opening is in contact with the top surface of the second gate electrode layer 1821. The opening (third opening) 1815c is provided such that the bottom of the opening is in contact with the top surface of the third gate electrode layer 1831. The opening (fourth opening) 1815d is provided such that the bottom of the opening is in contact with the top surface of the fourth gate electrode layer 1841.

The gate insulating layer 1806 is illustrated as a single layer in FIG. 18B. However, in this embodiment, the gate insulating layer 1806 is formed using a stacked layer of a silicon nitride film and a silicon oxide film over the silicon nitride film. Further, the oxide insulating layer 1809 is illustrated as a single layer in FIG. 18B. However, in this embodiment, the oxide insulating layer 1809 is formed using a stacked layer of a silicon oxide film and a silicon nitride film over the silicon oxide film.

Note that the first thin film transistor 1801, the second thin film transistor 1802, the third thin film transistor 1803, and the fourth thin film transistor 1804 can be formed in accordance with Embodiment 1 or Embodiment 3.

In the case where heating at 650° C. or higher is performed after a film to be the oxide semiconductor layer 1807 is formed or the film is processed into an island shape, the shape of the substrate 1800 which is a glass substrate might be changed (e.g., a change in size due to contraction). Thus, a problem might arise in a light exposure step where a mask alignment is needed, depending on a design rule of an integrated circuit. The position of a wiring such as a gate electrode layer and the position of a contact hole are comparatively misaligned, which makes it difficult to complete an element in an originally designed size.

As illustrated in FIG. 18A, the area of the oxide semiconductor layer 1807 is enlarged and the area of the gate electrode layer is enlarged. With such a structure, a thin film transistor can be manufactured without problems even if the shape of the substrate 1800 is changed by high-temperature heat treatment.

This embodiment can be freely combined with any one of Embodiments 1 to 8.

### Embodiment 10

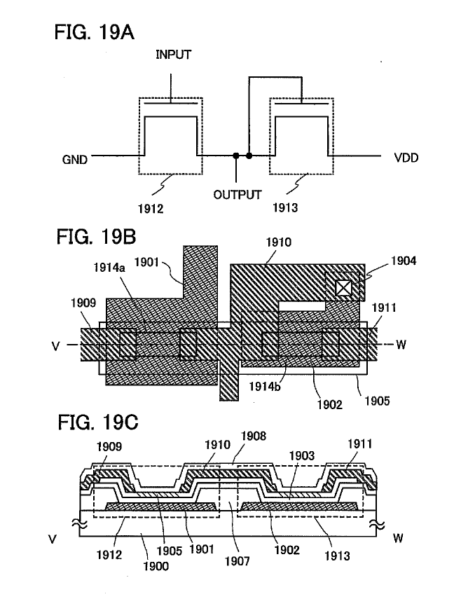

In this embodiment, an example of an inverter circuit using a thin film transistor is described with reference to FIGS. 19A to 19C.

In a display device, when at least part of a driver circuit for driving a pixel portion is formed using a thin film transistor including an oxide semiconductor, the circuit is formed using n-channel TFTs, and a circuit illustrated in FIG. 19A is used as a basic unit.

In addition, in the driver circuit, a gate electrode is directly connected to a source wiring or a drain wiring, whereby a favorable contact can be obtained, which leads to a reduction in contact resistance.

FIG. 19C illustrates a cross-sectional structure of an inverter circuit of a driver circuit. In FIG. 19C, a first gate electrode 1901 and a second gate electrode 1902 are provided over a substrate 1900. The first gate electrode 1901 and the second gate electrode 1902 can be formed to have a single-layer structure or a stacked-layer structure using a metal material such as molybdenum, titanium, chromium, tantalum, tungsten, aluminum, copper, neodymium, or scandium, and/or an alloy material which contains any of these materials as its main component.

An insulating layer 1907 is formed in contact with side surfaces of the first gate electrode 1901 and the second gate electrode 1902. Openings 1914a and 1914b in the insulating layer 1907 are provided such that the bottom of the opening is in contact with the top surfaces of the gate electrodes. Further, over a gate insulating layer 1903 covering the top surfaces of the gate electrodes, an oxide semiconductor layer 1905 overlapping with the gate insulating layer 1903 and the first gate electrode 1901 is formed.

Further, a first wiring 1909, a second wiring 1910, and a third wiring 1911 are provided over the oxide semiconductor layer 1905. The second wiring 1910 is directly connected to the second gate electrode 1902 in a contact hole 1904 formed in the gate insulating layer 1903. A protective insulating layer 1908 covering the first wiring 1909, the second wiring 1910, and the third wiring 1911 is provided. The protective insulating layer 1908 is formed using a silicon oxide film, a silicon nitride film, or the like by a sputtering method. In this embodiment, a silicon oxide film is formed by a sputtering method, and a silicon nitride film is formed over the silicon oxide film without exposure to the air.

A first thin film transistor 1912 includes the first gate electrode 1901, and the oxide semiconductor layer 1905 overlapping with the first gate electrode 1901 with the gate insulating layer 1903 interposed between the first gate electrode 1901 and the oxide semiconductor layer 1905. The first wiring 1909 is a power supply line at a ground potential (ground power supply line). This power supply line at a ground potential may be a power supply line to which a negative voltage VDL is applied (a negative power supply line).

In addition, a second thin film transistor 1913 includes the second gate electrode 1902, and the oxide semiconductor layer 1905 overlapping with the second gate electrode 1902 with the gate insulating layer 1903 interposed between the second gate electrode 1902 and the oxide semiconductor layer 1905. The third wiring 1911 is a power supply line to which a positive voltage VDD is applied (a positive power supply line).

A top view of the inverter circuit of the driver circuit is illustrated in FIG. 19B. In FIG. 19B, a cross section taken along chain line V-W corresponds to FIG. 19C.

As illustrated in FIGS. 19B and 19C, the second wiring 1910 is directly connected to the second gate electrode 1902 of the second thin film transistor 1913, in the contact hole 1904 formed in the gate insulating layer 1903. The second wiring 1910 and the second gate electrode 1902 are directly connected to each other, whereby favorable contact can be obtained, which leads to reduction in contact resistance.

Note that in the case where the pixel portion and the driver circuit are provided over the same substrate, on/off of voltage applied to a pixel electrode is switched by using enhancement-type transistors arranged in matrix, in the pixel portion. An oxide semiconductor is used for these enhancement-type transistors arranged in the pixel portion. Since the enhancement-type transistor has electric characteristics such as an on/off ratio of 10⁹ or more at a gate voltage of +20 V and a gate voltage of −20 V, leakage current is small and low power consumption driving can be realized.

This embodiment can be freely combined with any one of Embodiments 1 to 9.

### Embodiment 11

A semiconductor device disclosed in this specification can be applied to a variety of electronic appliances (including game machines) Examples of electronic appliances are a television set (also referred to as a television or a television receiver), a monitor of a computer or the like, a camera such as a digital camera or a digital video camera, a digital photo frame, a mobile phone (also referred to as a mobile phone device), a portable game console, a portable information terminal, an audio reproducing device, a large-sized game machine such as a pachinko machine, and the like.

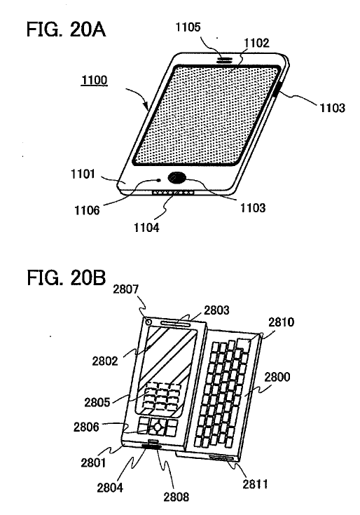

FIG. 20A illustrates an example of a mobile phone 1100. The mobile phone 1100 is provided with a display portion 1102 incorporated in a housing 1101, operation buttons 1103, an external connection port 1104, a speaker 1105, a microphone 1106, and the like.

In the mobile phone 1100 illustrated in FIG. 20A, data can be input when by touching the display portion 1102 with a finger or the like. Further, operations such as making calls, composing mails, or the like can be performed by touching the display portion 1102 with a finger or the like.

There are mainly three screen modes of the display portion 1102. The first mode is a display mode mainly for displaying images. The second mode is an input mode mainly for inputting data such as text. The third mode is a display-and-input mode in which two modes of the display mode and the input mode are combined.

For example, in the case of making a call or composing a mail, a text input mode mainly for inputting text is selected for the display portion 1102 so that text displayed on a screen can be input. In that case, it is preferable to display a keyboard or number buttons on almost all area of the screen of the display portion 1102.

When a detection device including a sensor for detecting inclination, such as a gyroscope or an acceleration sensor, is provided inside the mobile phone 1100, display on the screen of the display portion 1102 can be automatically switched by determining the direction of the mobile phone 1100 (whether the mobile phone 1100 is placed horizontally or vertically for a landscape mode or a portrait mode).

The screen modes are switched by touching the display portion 1102 or operating the operation button 1103 of the housing 1101. Alternatively, the screen modes may be switched depending on the kind of the image displayed on the display portion 1102. For example, when a signal of an image displayed on the display portion is a signal of moving image data, the screen mode is switched to the display mode. When the signal is a signal of text data, the screen mode is switched to the input mode.

Further, in the input mode, when input by touching the display portion 1102 is not performed for a certain period while a signal detected by the optical sensor in the display portion 1102 is detected, the screen mode may be controlled so as to be switched from the input mode to the display mode.

The display portion 1102 can also function as an image sensor. For example, an image of a palm print, a fingerprint, or the like is taken when the display portion 1102 is touched with a palm or a finger, whereby personal identification can be performed. Further, by providing a backlight or a sensing light source which emits a near-infrared light in the display portion, an image of a finger vein, a palm vein, or the like can be taken.

In the display portion 1102, a plurality of thin film transistors 410 whose parasitic capacitance is reduced, which is described in Embodiment 1, is arranged as switching elements for a pixel.

FIG. 20B illustrates another example of a mobile phone. A portable information terminal one example of which is shown in FIG. 20B can have a plurality of functions. For example, in addition to a telephone function, such a portable information terminal can have a function of processing a variety of pieces of data by incorporating a computer.

The portable information terminal illustrated in FIG. 20B includes a housing 2800 and a housing 2801. The housing 2801 includes a display panel 2802, a speaker 2803, a microphone 2804, a pointing device 2806, a camera lens 2807, an external connection terminal 2808, and the like. The housing 2800 includes a keyboard 2810, an external memory slot 2811, and the like. Further, an antenna is incorporated in the housing 2801.

Further, the display panel 2802 is provided with a touch panel. A plurality of operation keys 2805 which is displayed as images is illustrated by dashed lines in FIG. 20B.

Further, in addition to the above structure, a contactless IC chip, a small memory device, or the like may be incorporated.

The light-emitting device of the present invention can be used for the display panel 2802 and the direction of display is changed appropriately depending on an application mode. Further, the display device is provided with the camera lens 2807 on the same surface as the display panel 2802, and thus it can be used as a video phone. The speaker 2803 and the microphone 2804 can be used for videophone, recording, playback, and the like without being limited to verbal communication. Moreover, the housings 2800 and 2801 in a state where they are developed as illustrated in FIG. 20B can shift so that one is lapped over the other by sliding; therefore, the size of the portable information terminal can be reduced, which makes the portable information terminal suitable for being carried.

The external connection terminal 2808 can be connected to an AC adapter and various types of cables such as a USB cable, and charging and data communication with a personal computer are possible. Moreover, a large amount of data can be stored by inserting a storage medium into the external memory slot 2811 and can be moved.

Further, in addition to the above functions, an infrared communication function, a television reception function, or the like may be provided.

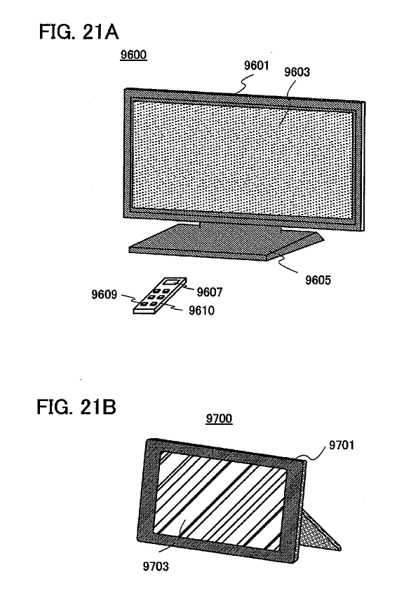

FIG. 21A illustrates an example of a television set 9600. In the television set 9600, a display portion 9603 is incorporated in a housing 9601. The display portion 9603 can display images. Here, the housing 9601 is supported by a stand 9605.

The television set 9600 can be operated with an operation switch of the housing 9601 or a separate remote controller 9610. Channels and volume can be controlled with an operation key 9609 of the remote controller 9610 so that an image displayed on the display portion 9603 can be controlled. Furthermore, the remote controller 9610 may be provided with a display portion 9607 for displaying data output from the remote controller 9610.

Note that the television set 9600 is provided with a receiver, a modem, and the like. With the use of the receiver, general television broadcasting can be received. Moreover, when the display device is connected to a communication network with or without wires via the modem, one-way (from a sender to a receiver) or two-way (between a sender and a receiver or between receivers) information communication can be performed.

In the display portion 9603, a plurality of thin film transistors 410 whose parasitic capacitance is reduced, which is described in Embodiment 1, is arranged as switching elements for a pixel.

FIG. 21B illustrates an example of a digital photo frame 9700. For example, in the digital photo frame 9700, a display portion 9703 is incorporated in a housing 9701. The display portion 9703 can display a variety of images. For example, the display portion 9703 can display data of an image taken with a digital camera or the like and function as a normal photo frame

In the display portion 9703, a plurality of thin film transistors 410 whose parasitic capacitance is reduced, which is described in Embodiment 1, is arranged as switching elements for a pixel.

Note that the digital photo frame 9700 is provided with an operation portion, an external connection portion (a USB terminal, a terminal that can be connected to various cables such as a USB cable, or the like), a recording medium insertion portion, and the like. Although these components may be provided on the surface on which the display portion is provided, it is preferable to provide them on the side surface or the back surface for the design of the digital photo frame 9700. For example, a memory storing data of an image taken with a digital camera is inserted in the recording medium insertion portion of the digital photo frame, whereby the image data can be transferred and then displayed on the display portion 9703.

The digital photo frame 9700 may be configured to transmit and receive data wirelessly. The structure may be employed in which desired image data is transferred wirelessly to be displayed.

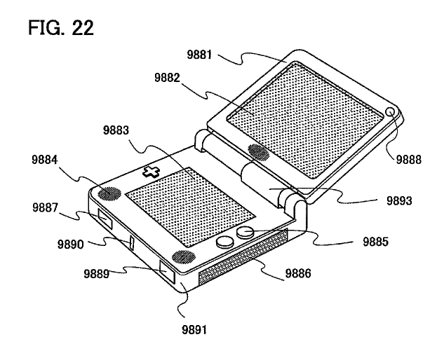

FIG. 22 is a portable game machine and is constituted by two housings of a housing 9881 and a housing 9891 which are connected with a joint portion 9893 so that the portable game machine can be opened or folded. A display portion 9882 and a display portion 9883 are incorporated in the housing 9881 and the housing 9891, respectively.

In the display portion 9883, a plurality of thin film transistors 410 whose parasitic capacitance is reduced, which is described in Embodiment 1, is arranged as switching elements for a pixel.

In addition, a portable amusement machine illustrated in FIG. 22 includes a speaker portion 9884, a recording medium insertion portion 9886, an LED lamp 9890, input means (an operation key 9885, a connection terminal 9887, a sensor 9888 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), and a microphone 9889), and the like. It is needless to say that the structure of the portable amusement machine is not limited to the above and other structures provided with at least a thin film transistor disclosed in this specification can be employed. The portable amusement machine may include other accessory equipment as appropriate. The portable amusement machine illustrated in FIG. 22 has a function of reading a program or data stored in a recording medium to display it on the display portion, and a function of sharing information with another portable amusement machine by wireless communication. Note that the functions of the portable amusement machine illustrated in FIG. 22 are not limited to those above, and a variety of functions can be provided.

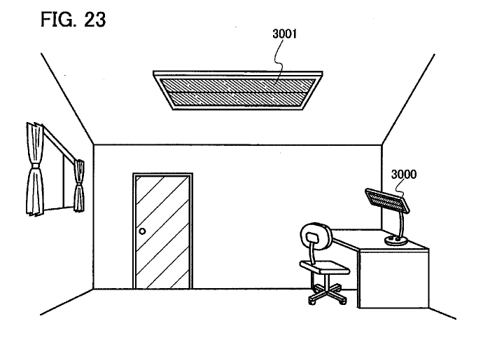

FIG. 23 is an example in which the light-emitting device formed in accordance with Embodiment 2 or Embodiment 7 is used as an indoor lighting device 3001. Since the light-emitting device described in Embodiment 2 or Embodiment 7 can be enlarged, the light-emitting device can be used as a lighting device having a large area. Further, the light-emitting device described in Embodiment 2 or Embodiment 7 can be used as a desk lamp 3000. Note that the lighting equipment includes in its category, a ceiling light, a wall light, a lightning for an inside of a car, an emergency exit light, and the like.

As described above, the thin film transistor described in Embodiment 1 or Embodiment 3 can be arranged in display panels of a variety of electronic appliances such as the above ones. With the use of, as a switching element of a display panel, the thin film transistor 410 whose parasitic capacitance is reduced, low power consumption can be realized and an electronic appliance with high reliability can be provided.

### Embodiment 12

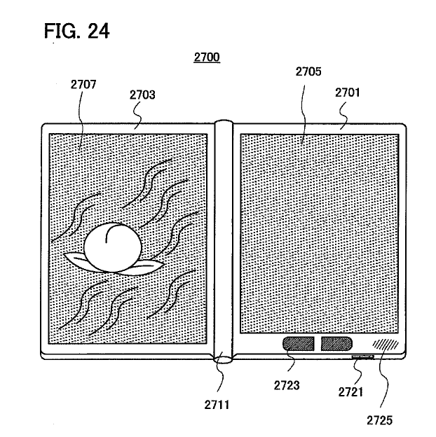

A semiconductor device disclosed in this specification can be applied to electronic paper. Electronic paper can be used for electronic appliances of a variety of fields as long as they can display data. For example, electronic paper can be applied to an e-book reader (electronic book), a poster, an advertisement in a vehicle such as a train, or displays of various cards such as a credit card. An example of the electronic appliances is illustrated in FIG. 24.

FIG. 24 illustrates an example of an e-book reader. For example, an e-book reader 2700 includes two housings, a housing 2701 and a housing 2703. The housing 2701 and the housing 2703 are combined with a hinge 2711 so that the e-book reader 2700 can be opened and closed with the hinge 2711 as an axis. With such a structure, the e-book reader 2700 can operate like a paper book.

A display portion 2705 and a display portion 2707 are incorporated in the housing 2701 and the housing 2703, respectively. The display portion 2705 and the display portion 2707 may display one image or different images. In the case where the display portion 2705 and the display portion 2707 display different images, for example, a display portion on the right side (the display portion 2705 in FIG. 24) can display text and a display portion on the left side (the display portion 2707 in FIG. 24) can display graphics.

FIG. 24 illustrates an example in which the housing 2701 is provided with an operation portion and the like. For example, the housing 2701 is provided with a power switch 2721, an operation key 2723, a speaker 2725, and the like. With the operation key 2723, pages can be turned. Note that a keyboard, a pointing device, or the like may also be provided on the surface of the housing, on which the display portion is provided. Furthermore, an external connection terminal (an earphone terminal, a USB terminal, a terminal that can be connected to various cables such as an AC adapter and a USB cable, or the like), a recording medium insertion portion, and the like may be provided on the back surface or the side surface of the housing. Moreover, the e-book reader 2700 may have a function of an electronic dictionary.

The e-book reader 2700 may have a configuration capable of wirelessly transmitting and receiving data. Through wireless communication, desired book data or the like can be purchased and downloaded from an electronic book server.

This embodiment can be implemented in appropriate combination with the thin film transistor described in Embodiment 1 or Embodiment 3, or the structure of electronic paper described in Embodiment 6.

This application is based on Japanese Patent Application serial no. 2009-215050 filed with Japan Patent Office on Sep. 16, 2009, the entire contents of which are hereby incorporated by reference.

1. A semiconductor device comprising:
a gate electrode layer over a substrate;
an insulating layer which is in contact with a side surface of the gate electrode layer and has a tapered side surface over the gate electrode layer;
over the insulating layer, a gate insulating layer which is thinner than the insulating layer and is in contact with a top surface of the gate electrode layer;
an oxide semiconductor layer over the gate insulating layer;
a source electrode layer and a drain electrode layer over a stack including the insulating layer, the gate insulating layer, and the oxide semiconductor layer; and
an oxide insulating layer in contact with the oxide semiconductor layer, over the source electrode layer and the drain electrode layer.

2. The semiconductor device according to claim 1,
wherein the gate insulating layer has a stacked-layer structure.

3. The semiconductor device according to claim 1,
wherein an aluminum oxide film or a silicon oxide film formed by a sputtering method is used as the oxide insulating layer.

4. The semiconductor device according to claim 1,
wherein the oxide semiconductor layer contains In, Ga and Zn.

5. An electronic device including the semiconductor device according to claim 1,
wherein the electronic device is selected from the group consisting of a television set, a computer, a mobile device, an electronic paper, a game machine and a lighting device.

6. A semiconductor device comprising:
a gate electrode layer over a substrate;
an insulating layer which is in contact with a side surface of the gate electrode layer and has a tapered side surface over the gate electrode layer;
over the insulating layer, a gate insulating layer which is thinner than the insulating layer and is in contact with a top surface of the gate electrode layer;
an oxide semiconductor layer over the gate insulating layer;
a source electrode layer and a drain electrode layer over the oxide semiconductor layer; and
an oxide insulating layer in contact with a side surface of the oxide semiconductor layer, over the source electrode layer and the drain electrode layer.

7. The semiconductor device according to claim 6,
wherein the gate insulating layer has a stacked-layer structure.

8. The semiconductor device according to claim 6,
wherein an aluminum oxide film or a silicon oxide film formed by a sputtering method is used as the oxide insulating layer.

9. The semiconductor device according to claim 6,
wherein the oxide semiconductor layer contains In, Ga and Zn.

10. An electronic device including the semiconductor device according to claim 6,
wherein the electronic device is selected from the group consisting of a television set, a computer, a mobile device, an electronic paper, a game machine and a lighting device.

11. A method for manufacturing a semiconductor device, comprising the steps of:
forming a gate electrode layer over a substrate,
forming an insulating film covering the gate electrode layer,
forming an insulating layer covering a side surface of the gate electrode layer, by forming an opening reaching a top surface of the gate electrode layer through selective etching of the insulating film,
over the insulating layer, forming a gate insulating layer which is thinner than the insulating layer and is in contact with the top surface of the gate electrode layer,
forming an oxide semiconductor layer over the gate insulating layer,
forming a source electrode layer and a drain electrode layer over a stack including the insulating layer, the gate insulating layer, and the oxide semiconductor layer, and
forming an oxide insulating layer in contact with the oxide semiconductor layer, over the source electrode layer and the drain electrode layer.

12. The method for manufacturing a semiconductor device according to claim 11,
wherein the insulating film is formed using a film formation apparatus which is different from a film formation apparatus used for forming the gate insulating layer, and
wherein the gate insulating layer is formed using a high-density plasma apparatus.

13. The method for manufacturing a semiconductor device according to claim 11,
wherein the gate insulating layer has a stacked-layer structure.

14. The method for manufacturing a semiconductor device according to claim 11,
wherein an aluminum oxide film or a silicon oxide film formed by a sputtering method is used as the oxide insulating layer.

15. The method for manufacturing a semiconductor device according to claim 11,
wherein the oxide semiconductor layer contains In, Ga and Zn.

16. An electronic device including the semiconductor device according to claim 11,
wherein the electronic device is selected from the group consisting of a television set, a computer, a mobile device, an electronic paper, a game machine and a lighting device.
